(19) United States
(12) Patent Application Publication
(10) Pub. No.: US 2023/0189589 A1
(43) Pub. Date: Jun. 15, 2023

(54) DISPLAY APPARATUS AND MULTI SCREEN DISPLAY APPARATUS INCLUDING THE SAME

(71) Applicant: LG Display Co., Ltd., Seoul (KR)

(72) Inventors: YoungHo JEON, Paju-si (KR); Seokho SHIM, Paju-si (KR)

(21) Appl. No.: 18/062,931

(22) Filed: Dec. 7, 2022

(30) Foreign Application Priority Data
Dec. 9, 2021 (KR) 10-2021-0175903

(51) Int. Cl. H10K 59/131

(52) U.S. Cl. CPC H01L 27/3276; H01L 27/3223

(57) ABSTRACT

A display apparatus having a thin bezel width while preventing deterioration in reliability of a light emitting element due to moisture permeation from occurring and a multi-screen display apparatus including the same are provided. The display apparatus includes a substrate having a display portion, a plurality of pixels displayed in the display portion, a pad portion spaced apart from the plurality of pixels and disposed at an edge portion of one side of the substrate, a dummy portion surrounding the display portion and disposed between the pad portion and the plurality of pixels, a pad connection line crossing the dummy portion and connected to each of the pad portions, and a connection portion electrically connecting the dummy portion with the pad connection line.

### CROSS-REFERENCE TO RELATED APPLICATIONS

This application claims the benefit of the Korean Patent Application No. 10-2021-0175903 filed on Dec. 9, 2021, which is hereby incorporated by reference as if fully set forth herein.

### BACKGROUND

### Technical Field

The present disclosure relates to a display apparatus for displaying an image and a multi-screen display apparatus including the same.

### Description of the Related Art

With the advancement of the information age, the demand for a display apparatus for displaying an image has increased in various forms. Therefore, various types of display apparatuses such as a liquid crystal display (LCD) apparatus, a plasma display panel (PDP) apparatus, an organic light emitting display (OLED) apparatus and a quantum dot light emitting display (QLED) apparatus have been recently used.

Among the display apparatuses, the organic light emitting display (OLED) apparatus and the quantum dot light emitting display (QLED) apparatus are self-light emitting types and have advantages in that a viewing angle and a contrast ratio are more excellent than those of the liquid crystal display (LCD) apparatus. Also, since the organic light emitting display (OLED) apparatus and the quantum dot light emitting display (QLED) apparatus do not require a separate backlight, it is advantageous that the organic light emitting display (OLED) apparatus and the quantum dot light emitting display (QLED) apparatus are able to be thin and lightweight and have low power consumption.

Meanwhile, the organic light emitting display apparatus displays an image through light emission of a light emitting element layer that includes a light emitting element interposed between two electrodes. In this case, light generated by light emission of the light emitting element is emitted to the outside through an electrode, a substrate, etc.

The organic light emitting display apparatus includes a display panel embodied to display an image. The display panel may include a display area having a plurality of pixels for displaying an image, and a bezel area surrounding the display area.

### BRIEF SUMMARY

The organic light emitting display apparatus of the related art requires a bezel (or mechanism) for covering a bezel area disposed on an edge (or edge portion) of the display panel, and a bezel width may be increased due to a width of the mechanism. In addition, when the bezel width of the organic light emitting display apparatus is extremely reduced, reliability of the light emitting element may be deteriorated due to degradation of the light emitting element due to moisture permeation.

Recently, a multi-screen display apparatus that implements a large screen by arranging a plurality of display apparatuses in a grid shape has been commercialized.

However, in the multi-screen display apparatus of the related art, a boundary portion called a seam exists between adjacent display apparatuses due to a bezel area or bezel of each of the display apparatuses. This boundary portion reduces immersion of an image by giving a sense of disconnection (or discontinuity) of the image when displaying one image on an entire screen of the multi-screen display apparatus.

The present disclosure has been formed in view of the various technical problems in the related art including the above identified problems.

One or more embodiments of the present disclosure provide a display apparatus having a thin bezel width while preventing deterioration in reliability of a light emitting element due to moisture permeation from occurring and a multi-screen display apparatus including the same.

In addition to the technical benefits of the present disclosure as mentioned above, additional benefits and features of the present disclosure will be clearly understood by those skilled in the art from the following description of the present disclosure.

In accordance with an aspect of the present disclosure, the above and other objects can be accomplished by the provision of a display apparatus comprising a substrate having a display portion, a plurality of pixels disposed in the display portion, pad portions spaced apart from the plurality of pixels and disposed at an edge portion of one side of the substrate, a dummy portion surrounding the display portion and disposed between the pad portion and the plurality of pixels, a pad connection line crossing the dummy portion and connected to each of the pad portions, and a connection portion electrically connecting the dummy portion with the pad connection line.

In accordance with an aspect of the present disclosure, the above and other objects can be accomplished by the provision of a multi-screen display apparatus comprising a plurality of display modules disposed along at least one of a first direction and a second direction crossing the first direction, wherein each of the plurality of display modules includes a substrate having a display portion, a plurality of pixels disposed in the display portion, pad portions spaced apart from the plurality of pixels and disposed at an edge portion of one side of the substrate, a dummy portion surrounding the display portion and disposed between the pad portion and the plurality of pixels, a pad connection line crossing the dummy portion and connected to each of the pad portions, and a connection portion electrically connecting the dummy portion with the pad connection line.

Details according to various embodiments of the present disclosure in addition to the above objects are included in the detailed description and drawings.

### BRIEF DESCRIPTION OF THE SEVERAL VIEWS OF THE DRAWINGS

The above and other objects, features and other advantages of the present disclosure will be more clearly understood from the following detailed description taken in conjunction with the accompanying drawings, in which:

FIG. 1 is a view illustrating a display apparatus according to one embodiment of the present disclosure;

FIG. 2 is an enlarged view illustrating a portion A shown in FIG. 1;

FIG. 3 is a cross-sectional view taken along line I-I′ shown in FIG. 1;

FIG. 4 is an enlarged view illustrating a portion B shown in FIG. 3;

FIG. 5 is a view illustrating a display apparatus according to another embodiment of the present disclosure;

FIG. 6 is a cross-sectional view taken along line II-II′ shown in FIG. 5;

FIG. 7 is an enlarged view illustrating a portion C shown in FIG. 5;

FIG. 8A is a cross-sectional view taken along line III-III′ shown in FIG. 7;

FIG. 8B is a cross-sectional view taken along line IV-IV′ shown in FIG. 7;

FIG. 8C is a cross-sectional view taken along line V-V′ shown in FIG. 7;

FIG. 8D is a cross-sectional view taken along line VI-VI′ shown in FIG. 7;

FIG. 9 is a schematic front view illustrating a display apparatus according to one embodiment of the present disclosure;

FIG. 10A is a view illustrating one subpixel according to one example shown in FIG. 9;

FIG. 10B is a view illustrating one subpixel according to another example shown in FIG. 9;

FIG. 11 is a view illustrating a multi-screen display apparatus according to one embodiment of the present disclosure; and

FIG. 12 is a cross-sectional view taken along line VII-VII′ shown in FIG. 11.

### DETAILED DESCRIPTION

Reference will now be made in detail to the embodiments of the present disclosure, examples of which are illustrated in the accompanying drawings. Wherever possible, the same reference numbers will be used throughout the drawings to refer to the same or like parts. Advantages and features of the present disclosure, and implementation methods thereof will be clarified through following embodiments described with reference to the accompanying drawings.

The present disclosure may, however, be embodied in different forms and should not be construed as limited to the embodiments set forth herein.

Rather, these embodiments are provided so that this disclosure will be thorough and complete, and will fully convey the scope of the present disclosure to those skilled in the art.

A shape, a size, dimension (e.g., length, width, height, thickness, radius, diameter, area, etc.)a ratio, an angle, and a number of elements disclosed in the drawings for describing embodiments of the present disclosure are merely an example, and thus, the present disclosure is not limited to the illustrated details. Like reference numerals refer to like elements throughout.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In the following description, when the detailed description of the relevant known function or configuration is determined to unnecessarily obscure the important point of the present disclosure, the detailed description will be omitted.

In a case where ‘comprise,’ ‘have,’ and ‘include’ described in the present specification are used, another part may be added unless ‘only∼’ is used. The terms of a singular form may include plural forms unless referred to the contrary.

In construing an element, the element is construed as including an error range although there is no explicit description.

In describing a position relationship, for example, when a position relation between two parts is described as ‘on∼,’ ‘over∼,’ ‘under∼’, and ‘next∼,’ one or more other parts may be disposed between the two parts unless ‘just’ or ‘direct’ is used.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

“X-axis direction,” “Y-axis direction” and “Z-axis direction” should not be construed by a geometric relation only of a mutual vertical relation and may have broader directionality within the range that elements of the present disclosure may act functionally.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in co-dependent relationship.

Hereinafter, a display apparatus and a multi-screen display apparatus including the same according to various embodiments of the present disclosure will be described in detail with reference to the accompanying drawings. In the drawings, the same or similar elements are denoted by the same reference numerals even though they are depicted in different drawings. Since a scale of each of elements shown in the accompanying drawings is different from an actual scale for convenience of description, the present disclosure is not limited to the shown scale.

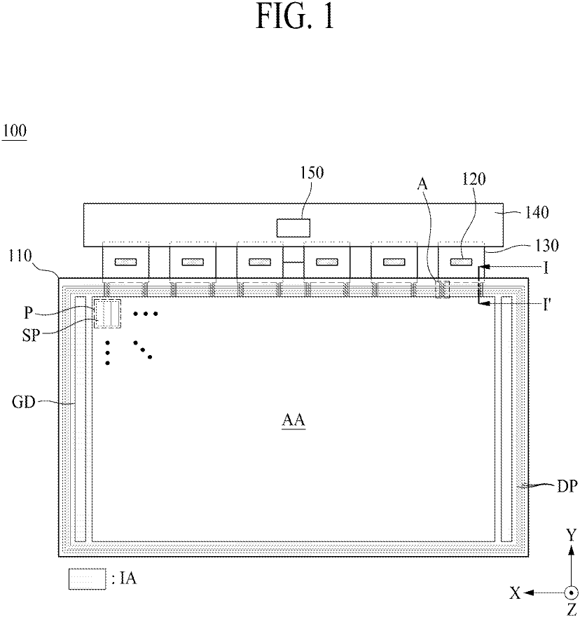

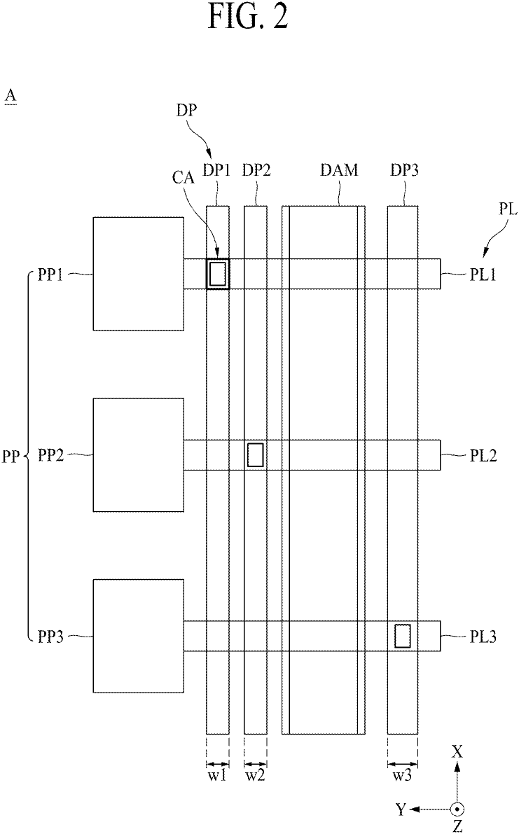

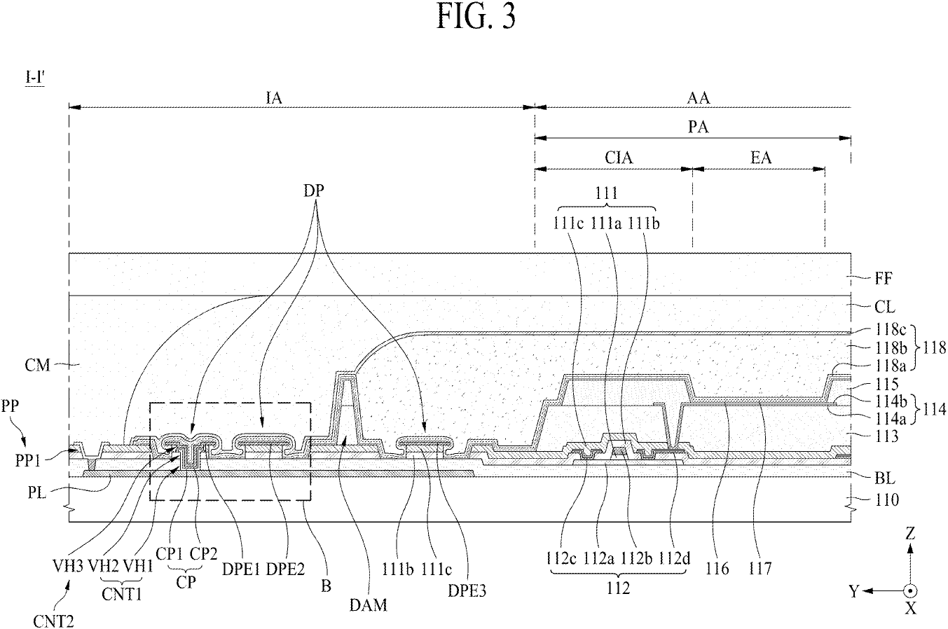

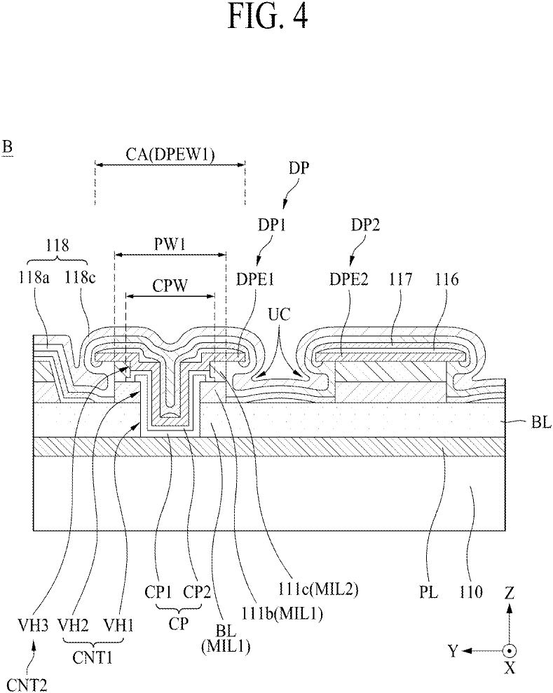

FIG. 1 is a view illustrating a display apparatus according to one embodiment of the present disclosure, FIG. 2 is an enlarged view illustrating a portion A shown in FIG. 1, FIG. 3 is a cross-sectional view taken along line I-I′ shown in FIG. 1, and FIG. 4 is an enlarged view illustrating a portion B shown in FIG. 3.

Referring to FIGS. 1 to 4, a display apparatus 100 according to one embodiment of the present disclosure may include a substrate 110, a source drive integrated circuit (IC) 120, a flexible film 130, a circuit board 140, and a timing controller 150.

The substrate 110 may include a lower substrate and an upper substrate, which are bonded to each other. The lower substrate may include a gate driver GD, but is not limited thereto. The substrate 110 may have a structure in which a film is covered on a single substrate rather than a bonding substrate.

The substrate 110 may be a glass substrate, or may be a thin type glass substrate or plastic substrate, which may be bent or curved. The substrate 110 may include a display portion AA, and a non-display portion IA surrounding the display portion AA. The display portion AA may further include a plurality of pixels P, each of which includes a plurality of subpixels SP, and a thin film transistor 112.

The display portion AA is an area where an image is displayed, and may be a pixel array area, an active area, a pixel array unit, a display unit or a screen. For example, the display portion AA may be disposed at a portion other than an edge portion of the substrate 110.

The non-display portion IA may be a non-light emission area in which an image is not displayed, and may be expressed as a non-display area, a non-active area or a non-active portion. For example, the non-display portion IA may be disposed on an edge portion of the substrate 110. The non-display portion IA may include a pad portion PP, a dummy portion DP, a pad connection line PL, and a connection portion CP.

Each of the plurality of pixels P may be individually disposed in each of a plurality of pixel areas defined in the display portion AA. Each of the plurality of pixel areas may be defined by pixel driving lines disposed in the display portion AA, for example, a plurality of gate lines and a plurality of data lines.

Each of the plurality of pixels P is disposed in each pixel area on the substrate 110, and displays a color image corresponding to a gate signal supplied from an adjacent gate line and a data voltage supplied from an adjacent data line.

Each of the plurality of pixels P may include a plurality of subpixels SP adjacent to each other. The subpixel SP may be defined as an area of a minimum unit, in which light is actually emitted. For example, at least three subpixels adjacent to one another may constitute one pixel P or unit pixel P for displaying a color image.

The pixel P according to one example may include first to third subpixels SP arranged to be adjacent to one another along a first direction X. In this case, the first subpixel may be a red subpixel, the second subpixel may be a green subpixel, the third subpixel may be a blue subpixel, but the present disclosure is not limited thereto.

The pixel P according to another example may include first to fourth subpixels SP arranged to be adjacent to one another along at least one of the first direction X and a second direction Y. In this case, the first subpixel may be a red subpixel, the second subpixel may be a white subpixel, the third subpixel may be a blue subpixel, and the fourth subpixel may be a green subpixel, but the present disclosure is not limited thereto.

According to one example, the light emitting element layers respectively disposed in the first to fourth subpixels SP may individually emit light of different colors or commonly emit white light.

When each of the first to fourth subpixels SP commonly emits white light, the first, third and fourth subpixels SP may include their respective color filters (or different wavelength conversion members) for converting white light into light of different colors. In this case, the second subpixel according to an example may not include a color filter. At least a portion of the second subpixel according to another example may include the same color filter as that of any one of the first, third and fourth subpixels.

The source drive IC 120 receives digital video data and a source control signal from the timing controller 150. The source drive IC 120 converts the digital video data into analog data voltages in accordance with the source control signal and supplies the analog data voltages to the data lines. When the source drive IC 120 is manufactured as a driving chip, the source drive IC 120 may be packaged in the flexible film 130 in a chip on film (COF) method or a chip on plastic (COP) method.

Pads, such as data pads, may be formed in the edge portion of the substrate 110. Lines connecting the pads with the source drive IC 120 and lines connecting the pads with lines of the circuit board 140 may be formed in the flexible film 130. The flexible film 130 may be attached onto the pads by using an anisotropic conducting film, whereby the pads may be connected with the lines of the flexible film 130.

The circuit board 140 may be attached to the flexible films 130. A plurality of circuits implemented as driving chips may be packaged in the circuit board 140. For example, the timing controller 150 may be packaged in the circuit board 140. The circuit board 140 may be a printed circuit board or a flexible printed circuit board.

The timing controller 150 receives the digital video data and a timing signal from an external system board through a cable of the circuit board 140. The timing controller 150 generates a gate control signal for controlling an operation timing of the gate driver GD and a source control signal for controlling an operation timing of the source drive ICs 120 based on the timing signal. The timing controller 150 supplies the gate control signal to the gate driver GD, and supplies the source control signal to the source drive ICs 120.

Meanwhile, each of the subpixels SP supplies a predetermined current to an organic light emitting element according to a data voltage of the data line when a gate signal from the gate line is input using a thin film transistor. Therefore, a light emitting portion of each of the subpixels SP may emit light with predetermined brightness in accordance with the predetermined current. Each of the first to fourth subpixels SP may include a circuit element layer 111 provided on an upper surface of a buffer layer BL, including a gate insulating layer 111a, an interlayer insulating layer 111b, a passivation layer 111c and a thin film transistor 112, a planarization layer 113 provided on the circuit element layer 111, a pixel electrode 114 provided on the planarization layer 113, a bank 115, an organic light emitting layer 116, a common electrode 117, and an encapsulation layer 118. The pixel electrode 114, the organic light emitting layer 116 and the common electrode 117 may be included in the light emitting element.

The buffer layer BL according to one example is provided on the substrate 110 to prevent water permeation to the thin film transistor 112. The buffer layer BL may be formed between the substrate 110 and the circuit element layer 111 (or gate insulating layer 111a) to protect the thin film transistor 112. The buffer layer BL may be disposed entirely on one surface (or front surface) of the substrate 110. The buffer layer BL may serve to prevent a material contained in the substrate 110 from diffusing into the transistor layer during a high temperature process of a manufacturing process of the thin film transistor.

The circuit element layer 111 may include a gate insulating layer 111a, an interlayer insulating layer 111b, a passivation layer 111c and a thin film transistor 112. The gate insulating layer 111a, the interlayer insulating layer 111b and the passivation layer 111c may be made of an inorganic material.

The thin film transistor 112 according to an example may include an active layer 112a, a gate electrode 112b, a source electrode 112c, and a drain electrode 112d.

The active layer 112a may include a channel area, a drain area and a source area, which are formed in a thin film transistor area of a circuit area of the pixel P. The drain area and the source area may be spaced apart from each other with the channel area interposed therebetween.

The active layer 112a may be formed of a semiconductor material based on any one of amorphous silicon, polycrystalline silicon, oxide and organic material.

The gate insulating layer 111a may be formed on the channel area of the active layer 112a. As an example, the gate insulating layer 111a may be formed in an island shape only on the channel area of the active layer 112a, or may be formed on an entire front surface of the first substrate 110 or the buffer layer BL, which includes the active layer 112a.

The gate electrode 112b may be formed on the gate insulating layer 111a to overlap the channel area of the active layer 112a.

The interlayer insulating layer 111b may be formed on the gate electrode 112b and the drain area and the source area of the active layer 112a. The interlayer insulating layer 111b may be formed in the circuit area and an entire light emission area, in which light is emitted to the pixel P. For example, the interlayer insulating layer 111b may be made of an inorganic material, but is not necessarily limited thereto.

The source electrode 112c may be electrically connected to the source area of the active layer 112a through a source contact hole provided in the interlayer insulating layer 111b overlapped with the source area of the active layer 112a.

The drain electrode 112d may be electrically connected to the drain area of the active layer 112a through a drain contact hole provided in the interlayer insulating layer 111b overlapped with the drain area of the active layer 112a.

The drain electrode 112d and the source electrode 112c may be made of the same metal material. For example, each of the drain electrode 112d and the source electrode 112c may be made of a single metal layer, a single layer of an alloy or a multi-layer of two or more layers, which is the same as or different from that of the gate electrode.

In addition, the circuit area may further include first and second switching thin film transistors disposed together with the thin film transistor 112, and a capacitor. Since each of the first and second switching thin film transistors is provided on the circuit area of the pixel P to have the same structure as that of the thin film transistor 112, its description will be omitted. The capacitor may be provided in an overlap area between the gate electrode 112b and the source electrode 112c of the thin film transistor 112, which overlap each other with the interlayer insulating layer 111b interposed therebetween.

Additionally, in order to prevent a threshold voltage of the thin film transistor provided in a pixel area from being shifted by light, the display panel or the substrate 110 may further include a light shielding layer (not shown) provided below the active layer 112a of at least one of the thin film transistor 112, the first switching thin film transistor or the second switching thin film transistor. The light shielding layer may be disposed between the substrate 110 and the active layer 112a to shield light incident on the active layer 112a through the substrate 110, thereby reducing or minimizing a change in the threshold voltage of the transistor due to external light.

The passivation layer 111c may be provided on the substrate 110 to cover the pixel area in which the pixel P is disposed. The passivation layer 111c covers the drain electrode 112d and the source electrode 112c of the thin film transistor 112 and the interlayer insulating layer 111b. The passivation layer 111c may be entirely formed in the circuit area and the light emission area. The passivation layer 111c may be omitted.

The planarization layer 113 may be formed on the substrate 110 to cover the passivation layer 111c. When the passivation layer 111c is omitted, the planarization layer 113 may be provided on the substrate 110 to cover the circuit area. The planarization layer 113 may be formed entirely in the circuit area and the light emission area.

The planarization layer 113 according to an example may be formed to be relatively thick, and thus may provide a flat surface on the display portion AA. For example, the planarization layer 113 may be made of an organic material such as photo acryl, benzocyclobutene, polyimide, and fluorine resin.

The planarization layer 113 according to one example may be formed to cover the circuit element layer 111 except the edge portion of the substrate 110. Therefore, the passivation layer 111c of the circuit element layer 111 disposed at the edge portion of the substrate 110 may be exposed without being covered by the planarization layer 113.

The light emitting element layer may be disposed on the planarization layer 113. The light emitting element layer according to one example may include a pixel electrode 114, an organic light emitting layer 116 and a common electrode 117.

The pixel electrode 114 may be expressed as an anode electrode, a reflective electrode, a lower electrode or a first electrode of the organic light emitting layer 116.

The pixel electrode 114 may be disposed on the planarization layer 113 that overlaps the light emission area EA of each pixel area PA. The pixel electrode 114 may be patterned in an island shape to be disposed in each pixel area PA, and may be electrically connected to source/drain electrodes 112c and 112d of a thin film transistor (or driving TFT) 112 of a corresponding pixel circuit. One side of the pixel electrode 114 may be extended onto the source/drain electrodes 112c and 112d of the thin film transistor 112, and may be electrically connected to the source/drain electrodes 112c and 112d of the thin film transistor 112 through a contact hole provided in the planarization layer 113.

The pixel electrode 114 according to one example may include a metal material having a low work function and excellent reflection efficiency.

As an example, when the display apparatus 100 is provided in a top emission mode, the pixel electrode 114 may be formed of a metal material having high reflectance and a stacked structure of a metal material having high reflectance and a transparent metal material. For example, the pixel electrode 114 may have a stacked structure of a lower electrode 114a and an upper electrode 114b. The lower electrode 114a may be disposed between the planarization layer 113 and the upper electrode 114b, and may have a greater coupling force with the planarization layer 113 than that with the upper electrode 114b. The lower electrode 114a according to one example may be provided in a stacked structure (ITO/MoTi/ITO) of MoTi and ITO to enhance the coupling force with the planarization layer 113. The upper electrode 114b is disposed on an upper surface (or upper side) of the lower electrode 114a, that is, between the lower electrode 114a and the organic light emitting layer 116, and may be provided in a stacked structure (ITO/Ag/ITO) of Ag and ITO. The upper electrode 114b may have higher reflectance, which reflects light emitted from the organic light emitting layer 116, than the lower electrode 114a.

When the display apparatus 100 is provided in a bottom emission mode, the pixel electrode 114 may be formed of a transparent conductive material (TCO) such as ITO and IZO, which may transmit light, or a semi-transmissive conductive material such as magnesium (Mg), silver (Ag) or an alloy of magnesium (Mg) and silver (Ag).

As shown in FIG. 3, since the pixel electrode 114 is provided in the display portion AA, the planarization layer 113 may be provided below the pixel electrode 114 in the display portion AA. The planarization layer 113 is provided with a predetermined thickness so as to cover the thin film transistor 112 for allowing the organic light emitting layer 116 to emit light, and thus its upper surface may be flat. Therefore, the pixel electrode 114 provided on the planarization layer 113 may be also provided to be flat along a profile of the upper surface of the planarization layer 113.

A pixel electrode 114 may be used as a metal layer that implements first to third pad members PP1, PP2 and PP3 disposed in the pad portion PP. That is, pixel driving voltage pads, data pads, reference voltage pads, a plurality of pixel common voltage pads and gate pads, which are disposed in the pad portion PP, may be formed of the same material as that of the pixel electrode 114 together with the pixel electrode 114.

A bank 115 may be disposed in a non-light emission area in which light is not emitted, and may be provided to surround each of the light emission areas (or light emission portions) of a plurality of subpixels. That is, the bank 115 may partition (or define) each of the light emission areas (or light emission portions).

The bank 115 may be formed to cover the edge of the pixel electrode 114, thereby partitioning (or defining) the light emission areas (or light emitting portions) of the plurality of subpixels.

The bank 115 may be formed to cover the edge of each of the pixel electrodes 114 of the subpixels and expose a portion of each of the pixel electrodes 114. Therefore, the bank 115 may prevent a short circuit between the pixel electrode 114 and the common electrode 117 at the edge of the pixel electrode 114. The exposed portion of the pixel electrode 114, which is not covered by the bank 115, may be a light emission area (or light emitting portion).

The bank 115 may be formed of an organic layer such as an acrylic resin, an epoxy resin, a phenolic resin, a polyamide resin and a polyimide resin, but is not limited thereto.

The organic light emitting layer 116 is formed on the pixel electrode 114 and the bank 115. When a voltage is applied to the pixel electrode 114 and the common electrode 117, holes and electrons move to the organic light emitting layer 116, respectively, and are combined with each other in the organic light emitting layer 116 to emit light.

The organic light emitting layer 116 may be formed of a common layer provided on a plurality of subpixels SP and the bank 115. In this case, the organic light emitting layer 116 may be provided in a tandem structure in which a plurality of light emitting layers, for example, a yellow-green light emitting layer and a blue light emitting layer are stacked, and may emit white light when an electric field is formed between the pixel electrode 114 and the common electrode 117.

A color filter (not shown) corresponding to a color of a corresponding subpixel may be formed on each of a plurality of subpixels SP. For example, a red color filter may be provided in a red subpixel, a green color filter may be provided in a green subpixel, and a blue color filter may be provided in a blue subpixel. A white subpixel may not include a color filter because the organic light emitting layer 116 emits white light.

The common electrode 117 is formed on the organic light emitting layer 116. The common electrode 117 may be a second electrode or a cathode electrode. The common electrode 117 may be a common layer commonly formed in the subpixels. The common electrode 117 may be formed of a transparent metal material, a semi-transmissive metal material or a metal material having high reflectance.

When the display apparatus 100 is provided in a top emission mode, the common electrode 117 may be formed of a transparent conductive material (TCO) such as ITO and IZO, which may transmit light, or a semi-transmissive conductive material such as magnesium (Mg), silver (Ag) or an alloy of magnesium (Mg) and silver (Ag).

When the display apparatus 100 includes a bottom emission mode, the common electrode 117 may be formed of a metal material having high reflectance, such as a stacked structure (Ti/Al/Ti) of aluminum and titanium, a stacked structure (ITO/A1/ITO) of aluminum and ITO, Ag alloy and a stacked structure (ITO/Ag alloy/ITO) of Ag alloy and ITO. The Ag alloy may be an alloy of metal such as silver (Ag), palladium (Pd), copper (Cu), etc.

The encapsulation layer 118 is formed on the common electrode 117. The encapsulation layer 118 serves to prevent oxygen or moisture from being permeated into the organic light emitting layer 116 and the common electrode 117. Accordingly, in some embodiments, the encapsulation layer 118 may include at least one inorganic layer and at least one organic layer.

The display apparatus 100 according to one embodiment of the present disclosure may further include a cover layer CL disposed on the substrate 110.

The cover layer CL may be implemented to provide a flat surface while covering an encapsulation layer 118. The cover layer CL may be disposed in the display portion AA and the non-display portion IA. The cover layer CL according to one example may be made of an organic material. Optionally, the cover layer CL may further include a getter material capable of adsorbing moisture and/or oxygen.

The display apparatus 100 according to one embodiment of the present disclosure may further include a film FF disposed on the substrate 110.

The film FF may be disposed on the cover layer CL. For example, the film FF may be coupled to the cover layer CL via a transparent adhesive member.

The film FF according to one example may include an anti-reflective layer (or anti-reflective film) for preventing reflection of external light and improving outdoor visibility and a contrast ratio for an image displayed on the display apparatus. For example, the anti-reflective layer may include a circularly polarized layer (or circularly polarized film) that blocks reflective light that is reflected by a TFT and/or pixel driving lines disposed on the substrate 110 and again moves to the outside.

The film FF according to one example may further include a barrier layer (or barrier film) for primarily preventing moisture or oxygen permeation, wherein the barrier layer may be made of a material having low moisture permeability, for example, a polymer material.

The film FF according to one example may further include an optical path control layer (or optical path control film) for controlling a path of light emitted from each pixel P to the outside. The optical path control layer includes a structure in which a high refractive index layer and a low refractive index layer are alternately stacked, thereby changing a path of light incident from each pixel P to reduce or minimize a color shift phenomenon according to a viewing angle. Thus, the film FF may be a functional film having at least one of the above functions.

The display apparatus according to one embodiment of the present disclosure may further include a sealing member CM disposed on the substrate 110.

The sealing member CM may be formed between the substrate 110 and the film FF, and may cover both sides of each of a circuit element layer 111, a planarization layer 113 and the cover layer CL. That is, the sealing member CM may cover both sides of each of the circuit element layer 111, the planarization layer 113 and the cover layer CL, which are exposed to the outside of the display apparatus, between the film FF and the substrate 110. In addition, the sealing member CM may cover a portion of a flexible circuit film (not shown) attached to each pad portion PP at an edge portion of one side of the substrate 110 and spaced apart from the plurality of pixels. The sealing member CM may serve to prevent lateral light leakage by light, which is moving toward an outer side inside the cover layer CL, among light emitted from an organic light emitting layer 116 of each subpixel SP. In particular, the sealing member CM overlapped with the pad portion PP of the substrate 110 may serve to prevent or minimize reflection of external light due to the first to third pad members disposed in the pad portion PP.

Optionally, the sealing member CM may further include a getter material capable of adsorbing moisture and/or oxygen.

In the display apparatus 100 according to the present disclosure, the encapsulation layer 118 may be disposed in the display portion AA as well as the non-display portion IA as shown in FIG. 3. The encapsulation layer 118 according to one example may include a first inorganic layer 118a provided on a common electrode 117 of the display portion AA, an organic layer 118b provided on the first inorganic layer 118a, and a second inorganic layer 118c provided on the organic layer 118b. The organic layer 118b may be provided at a thickness sufficient to cover foreign materials (not shown) such as particles that occur when the light emitting element including the organic light emitting layer 116 is formed. If there is no organic layer 118b or the organic layer 118b is thin, the first inorganic layer 118a thinner than the particles may not cover the particles, or even though the first inorganic layer 118a covers the particles, the first inorganic layer 118a covering the particles may be more easily damaged by external impact than the first inorganic layer 118a positioned so as not to cover the particles, whereby cracks may occur. In this case, external moisture or humidity may be easily permeated into the display portion AA so that the light emitting element may be damaged. Therefore, the organic layer 118b of the encapsulation layer 118 may be provided to be thicker than the first inorganic layer 118a or the second inorganic layer 118c to prevent cracks from being easily generated due to external impact while sufficiently covering the particles.

The organic layer 118b according to one example may be extended to a dam DAM, which is provided in the non-display portion IA, as well as the display portion AA. The organic layer 118b may be formed by coating a liquid organic material, and the dam DAM may prevent the liquid organic material from flowing to the outside of the substrate 110. Therefore, as shown in FIG. 3, the organic layer 118b may be disposed in the display portion AA and an area between the display portion AA and the dam DAM.

Meanwhile, the first inorganic layer 118a and the second inorganic layer 118c may be provided to be extended to the non-display portion IA as well as the display portion AA. For example, the first inorganic layer 118a and the second inorganic layer 118c may be provided to be further extended toward an end of the substrate to cover the common electrode 117 provided to be extended from the display portion AA to the non-display portion IA and the dam DAM provided in the non-display portion IA.

As shown in FIG. 3, the first inorganic layer 118a may be disposed between the common electrode 117 provided in the display portion AA and the organic layer 118b and extended to the edge portion of the substrate 110 while covering the dam DAM provided in the non-display portion IA. Therefore, the first inorganic layer 118a may be provided to cover an upper surface and sides of the dam DAM while covering an entire lower surface of the organic layer 118b.

Likewise, the common electrode 117 may be provided to be extended from the display portion AA to the non-display portion IA to cover the upper surface and sides of the dam DAM. As a result, the first inorganic layer 118a and the common electrode 117 may doubly cover the upper surface and sides of the dam DAM, thereby preventing external moisture or humidity from being permeated into the display portion AA through the dam DAM.

The second inorganic layer 118c may be extended from the display portion AA to the non-display portion IA to cover the organic layer 118b, and may be in contact with the first inorganic layer 118a on the dam DAM. The second inorganic layer 118c may be in contact with the first inorganic layer 118a on the upper surface of the dam DAM, and may be further extended to the edge portion of the substrate 110 together with the first inorganic layer 118a. Therefore, as shown in FIG. 3, the second inorganic layer 118c may be provided even in the edge portion of the substrate 110 while covering an entire upper surface of the organic layer 118b and covering a portion of the upper surface and sides of the dam DAM.

As the first inorganic layer 118a and the second inorganic layer 118c are made of the same material, an adhesive force (or coverage) may be more improved than the case that the first inorganic layer 118a and the second inorganic layer 118c are made of their respective materials different from each other, whereby moisture penetration through the inorganic layer may be more effectively avoided.

Meanwhile, the organic light emitting layer 116 disposed below (on a lower surface of) the first inorganic layer 118a may be extended to the non-display portion IA as well as the display portion AA. The organic light emitting layer 116 may be disposed on the display portion and the dam. As the organic light emitting layer 116 is disposed even in the non-display portion IA, a sense of difference from the display portion AA may be reduced when the organic light emitting layer 116 of the display portion AA does not emit light. Meanwhile, when the organic light emitting layer 116 is positioned to be close to the outside or exposed to the outside, external moisture or humidity may be easily permeated through the organic light emitting layer 116, whereby the light emitting element may be damaged or lifespan of the light emitting element may be shortened. Therefore, the display apparatus 100 according to the present disclosure may be provided so that the dummy portion DP disconnects the organic light emitting layer 116 disposed in the non-display portion IA (or the edge portion of the substrate 110). Therefore, the display apparatus 100 according to the present disclosure may prevent moisture permeation through the organic light emitting layer 116 disposed in the non-display portion IA (or the edge portion of the substrate 110). The common electrode 117 disposed on the organic light emitting layer 116 in the non-display portion IA may be disconnected together with the organic light emitting layer 116 by the dummy portion DP. This will be described in detail with reference to the dummy portion DP.

Meanwhile, each of the plurality of gate lines may be disposed in the display portion AA on the substrate 110. For example, each of the plurality of gate lines may be longitudinally extended along the first direction X, and may be spaced apart from each other along the second direction Y crossing the first direction X. Each of the plurality of gate lines according to one example may include first and second gate lines disposed in parallel with each other along the first direction X.

Each of the plurality of data lines may be disposed in the display portion AA on the substrate 110 to cross each of the plurality of gate lines. For example, each of the plurality of data lines may be extended longitudinally along the second direction Y, and may be spaced apart from each other along the first direction X.

The pad portion PP includes a plurality of pad members, for example, a first pad member PP1, a second pad member PP2 and a third pad member PP3. Each of the first to third pad members PP1, PP2 and PP3 may be disposed at the edge portion of one side of the substrate 110 along the first direction X. The first to third pad members PP1, PP2 and PP3 may be spaced apart from each other at the edge portion of the substrate 110.

The first to third pad members PP1, PP2 and PP3 according to one example may be at least one of a plurality of pixel driving voltage pads electrically connected to one side of each of a plurality of pixel driving power lines, a plurality of data pads electrically connected to one side of each of the plurality of data lines, a plurality of reference voltage pads electrically connected to one side of each of a plurality of reference voltage lines and a plurality of pixel common voltage pads electrically connected to one side of each of the plurality of pixel common voltage lines.

A pad connection line PL may be connected to each pad portion PP. For example, each of the first to third pad connection lines PL1, PL2 and PL3 electrically connected to one of the plurality of pixel driving power lines, the plurality of data lines, the plurality of reference voltage lines and the plurality of pixel common voltage lines may be connected to each of the first to third pad members PP1, PP2 and PP3. The first pad connection line PL1, the second pad connection line PL2 and the third pad connection line PL3 may be expressed as a pad link line.

The dummy portion DP according to one example is disposed to surround the display portion AA between the pad portion PP and the plurality of pixels P. The dummy portion DP is disposed to intersect (or cross) the pad connection line PL, and is electrically connected to the pad connection line PL through the connection portion CP. The dummy portion DP may be electrically connected to the pad portion PP through the connection portion CP and the pad connection line PL, and thus may be maintained at the same potential as the plurality of pixel common voltage lines. Therefore, the dummy portion DP may discharge static electricity from the outside to the pad portion PP and/or the pixel common voltage line through the connection portion CP and the pad connection line PL, thereby preventing defects due to static electricity.

The connection portion CP according to one example may be disposed between the dummy portion DP and the pad connection line PL. The connection portion CP may electrically connect the dummy portion DP with the pad connection line PL. The connection portion CP is made of a metallic material, one side (or upper surface) of thereof may be connected to the dummy portion DP and the other side (or lower surface) thereof may be connected to the pad connection line PL, thereby electrically connecting the dummy portion DP with the pad connection line PL.

Meanwhile, the plurality of pixel common voltage lines may be electrically connected to the connection portion CP and the dummy portion DP, which are made a conductive material, so that the pixel common voltage supplied from the plurality of pixel common voltage lines to the common electrode may be more uniformly supplied to each of the plurality of pixels P disposed in the display portion AA. As a result, the common electrode may be electrically connected to the dummy portion DP through the pad portion PP, the pad connection line PL and the connection portion CP.

Referring to FIGS. 2 and 3, the display apparatus 100 according to one embodiment of the present disclosure may include a cross area CA.

The cross area CA according to one example may be an area where the dummy portion DP and the pad connection line PL cross each other, that is, an area where the pad connection line PL crosses the dummy portion DP. Therefore, the cross area CA may have a size corresponding to an area where the dummy portion DP and the pad connection line PL overlap each other in a thickness direction Z of the substrate 110.

The connection portion CP according to one example may electrically connect the dummy portion DP with the pad connection line PL in the cross area CA. Therefore, as shown in FIG. 4, a width CPW of the connection portion CP may be smaller than a width DPEW1 of the dummy portion DP (or first dummy electrode DPE1). In addition, the connection portion CP may overlap the pad connection line PL together with the dummy portion DP (or first dummy electrode DPE1) in the cross area CA. Therefore, the connection portion CP and the dummy portion DP may prevent moisture and the like from being permeated into the pad connection line PL, thereby preventing the pad connection line PL from being damaged due to moisture permeation.

Referring to FIG. 4, the display apparatus 100 according to one embodiment of the present disclosure may include a first middle insulating layer MIL1 and a second middle insulating layer MIL2.

The first middle insulating layer MIL1 according to one example may be disposed between the connection portion CP and the pad connection line PL. The first middle insulating layer MIL1 according to one example may include a buffer layer BL disposed on the pad connection line PL in the cross area CA, and an interlayer insulating layer 111b disposed on the buffer layer BL.

The first middle insulating layer MIL1 may include a first contact hole CNT1 for connecting the connection portion CP with the pad connection line PL. The connection portion CP may be electrically connected to the pad connection line PL through the first contact hole CNT1. In more detail, referring to FIG. 4, the connection portion CP may be disposed in a first via hole VH1 passing through the buffer layer BL disposed on the pad connection line PL in the cross area CA and a second via hole VH2 passing through the interlayer insulating layer 111b disposed on the first via hole VH1. The first contact hole CNT1 may include the first via hole VH1 and the second via hole VH2. Therefore, the connection portion CP is in contact with an upper surface of the pad connection line PL exposed from the first via hole VH1, so that the connection portion CP may be electrically connected to the pad connection line PL.

The second middle insulating layer MIL2 may be disposed between the dummy portion DP and the connection portion CP. The second middle insulating layer MIL2 according to one example may include a passivation layer 111c disposed on the interlayer insulating layer 111b in the cross area CA.

The second middle insulating layer MIL2 may include a second contact hole CNT2 for connecting the dummy portion DP with the connection portion CP. The dummy portion DP may be electrically connected to the connection portion CP through the second contact hole CNT2. In more detail, referring to FIG. 4, the dummy portion DP (or the first dummy electrode DPE1) may be disposed in a third via hole VH3 passing through the passivation layer 111c disposed on the second via hole VH2 in the cross area CA. The second contact hole CNT2 may include the third via hole VH3. Therefore, the dummy portion DP may be electrically connected to the connection portion CP by being in contact with an upper surface of the connection portion CP exposed from the third via hole VH3.

Meanwhile, the connection portion CP may include a first connection line CP1 disposed in the first via hole VH1 and the second via hole VH2, and a second connection line CP2 that is in contact with an upper surface of the first connection line CP1 and an upper surface of the interlayer insulating layer 111b. The first connection line CP1 according to one example may be made of a metal material such as Cu. The second connection line CP2 according to one example may be made of a transparent conductive material such as ITO.

As shown in FIG. 4, the display apparatus 100 according to one embodiment of the present disclosure may have a structural characteristic in which the first contact hole CNT1 and the second contact hole CNT2 overlap each other in the thickness direction Z of the substrate 110 in the cross area CA. That is, the first via hole VH1, the second via hole VH2 and the third via hole VH3 may overlap inside the cross-area CA. In accordance with this structure, the dummy portion DP and the connection portion CP may cover the upper surface of the pad connection line PL exposed in the cross area CA by overlap, so that moisture permeability to the pad connection line PL may be increased or maximized.

In the display apparatus 100 according to one embodiment of the present disclosure, the substrate 110 may further include a dam DAM disposed at an edge portion of the substrate 110 to surround the display portion AA.

The dam DAM may be disposed along the edge portion of the substrate 110 to have a closed loop shape surrounding the display portion AA. This dam DAM serves to block spreading or overflowing of the encapsulation layer 118 disposed on the substrate 110, thereby protecting the display portion AA. The dam DAM may be formed of the same material as that of at least one of the planarization layer 113 and the bank layer 115 disposed in the display portion AA.

The dam DAM may be implemented on the substrate 110 so that it surrounds the dummy portion DP or is surrounded by the dummy portion DP. For example, the dummy portion DP may be disposed in at least one of an inner area and an outer area of the dam DAM.

Referring to FIGS. 2 to 4, the dummy portion DP may include a first dummy line DP1 and a second dummy line DP2, which are provided in the outer area of the dam DAM, and a third dummy line DP3 provided in the inner area of the dam DAM.

The first dummy line DP1 may be disposed between the pad portion PP and the dam DAM. As shown in FIG. 2, the first dummy line DP1 may be provided to cross each of a first pad connection line PL1 connected to the first pad member PP1, a second pad connection line PL2 connected to the second pad member PP2, and a third pad connection line PL3 connected to the third pad member PP3. This is because that the first dummy line DP1 is provided in a closed loop shape surrounding the display portion AA at the edge portion of the substrate 110. As shown in FIG. 4, the first dummy line DP1 may include a first dummy electrode DPE1 electrically connected to the first pad connection line PL1.

The second dummy line DP2 may be disposed between the first dummy line DP1 and the dam DAM. As shown in FIG. 2, the second dummy line DP2 may be disposed along the first dummy line DP1 at a position spaced apart from the first dummy line DP1. Since the second dummy line DP2 is also provided in the form of a closed loop, the second dummy line DP2 may be provided to cross each of the first pad connection line PL1, the second pad connection line PL2 and the third pad connection line PL3. The second dummy line DP2 may include a second dummy electrode DPE2 electrically connected to the second pad connection line PL2.

The third dummy line DP3 may be disposed between the dam DAM and the display portion AA. The third dummy line DP3 may be provided in the form of a closed loop, and may be provided to cross each of the first pad connection line PL1, the second pad connection line PL2 and the third pad connection line PL3. The third dummy line DP3 may include a third dummy electrode DPE3 electrically connected to the third pad connection line PL3.

Referring to FIGS. 3 and 4, a width of each of the first dummy electrode DPE1, the second dummy electrode DPE2 and the third dummy electrode DPE3 may be wider than that of the passivation layer 111c disposed therebelow. For example, the cross area CA includes the buffer layer BL disposed on the pad connection line PL, the interlayer insulating layer 111b disposed on the buffer layer BL, and the passivation layer 111c disposed between the interlayer insulating layer 111b and the first dummy electrode DPE1, and a width DPEW1 of the first dummy electrode DPE1 disposed on the upper surface of the passivation layer 111c may be wider than a width PW1 of the passivation layer 111c. As shown in FIG. 4, since the first dummy electrode DPE1 is formed to be protruded more outwardly than the passivation layer 111c, the protruded portion of the first dummy electrode DPE1 serves as a mask to disconnect the organic light emitting layer 116 formed in a subsequent process. The organic light emitting layer 116 disposed in the non-display portion IA is disconnected by the first dummy electrode DPE1 (or the protruded portion of the first dummy electrode DPE1), whereby moisture penetration from the outside of the substrate 110 to the display portion AA may be avoided.

For this reason, the second dummy electrode DPE2 may have a width wider than that of the passivation layer 111c disposed at a lower portion in the cross area with the second pad connection line PL2. The third dummy electrode DPE3 may have a width wider than that of the passivation layer 111c disposed at a lower portion in the cross area with the third pad connection line PL3. Therefore, the display apparatus 100 according to one embodiment of the present disclosure may disconnect the organic light emitting layer 116 in the cross area of the dummy portion DP and the pad connection line PL, thereby improving an effect of preventing moisture permeation into the display portion AA. Although the organic light emitting layer 116 is disconnected in the cross area, the organic light emitting layer 116 disposed at the non-display portion IA or the edge portion of the substrate 110 may be disconnected by the first to third dummy lines DP1, DP2 and DP3 provided in the form of a closed loop.

The common electrode 117 formed on the organic light emitting layer 116 may be disconnected together with the organic light emitting layer 116 by the dummy portion DP, but is not limited thereto. The common electrode 117 provided on the non-display portion IA may be provided to be connected in one body without being disconnected.

Referring back to FIG. 2, a width of the third dummy electrode may be the same as or wider than a width W1 of the first dummy electrode. Referring to FIGS. 2 and 3, since the width of the third dummy electrode DPE3 is the same as that of the third dummy line DP3, the width of the third dummy electrode DPE3 may be a width W3 of the third dummy line DP3. As described above, since it is beneficial for the first to third dummy electrodes to have a width to disconnect the organic light emitting layer 116, the width W3 of the third dummy electrode DPE3 may be the same as or wider than the width W1 of the first dummy electrode. When the width W3 of the third dummy electrode DPE3 is wider than the width W1 of the first dummy electrode DPE1, the organic light emitting layer 116 extended from the display portion AA to the non-display portion IA may be primarily (or thirdly or finally) and completely disconnected. Therefore, prevention of moisture permeation into the display portion AA from the outside of the substrate 110 may be increased or maximized due to second disconnection of the organic light emitting layer 116 through the second dummy electrode DPE2 and third disconnection (or first disconnection) of the organic light emitting layer 116 through the first dummy electrode DPE1. The width W3 of the third dummy electrode DPE3 may be the same as or wider than the width W2 of the second dummy electrode.

Meanwhile, an undercut portion UC may be formed between the first dummy line DP1 and the second dummy line DP2 due to widths of the first and second dummy electrodes DPE1 and DPE2. The undercut portion UC according to one example may be disposed along the first dummy line DP1 or the second dummy line DP2. Therefore, the undercut portion UC may have a closed loop shape, and the organic light emitting layer 116 may be disconnected in the undercut portion UC. As shown in FIG. 4, a portion of the organic light emitting layer 116 disconnected by the dummy electrode may be disposed in the undercut portion UC. A portion of the cut common electrode 117 may be also disposed in the undercut portion UC.

As a result, in the display apparatus 100 according to one embodiment of the present disclosure, the organic light emitting layer 116 is disconnected by the dummy portion DP disposed at the edge portion of the substrate 110, so that moisture permeation into the display portion AA from the outside may be avoided, whereby reliability of the light emitting element may be improved. In addition, in the display apparatus 100 according to one embodiment of the present disclosure, the dummy electrode of the dummy portion DP is electrically connected to the pad connection line PL through the connection portion CP in the cross area CA of the pad connection line PL and the dummy portion DP disposed at the edge portion of the substrate 110, whereby defects due to static electricity may be avoided.

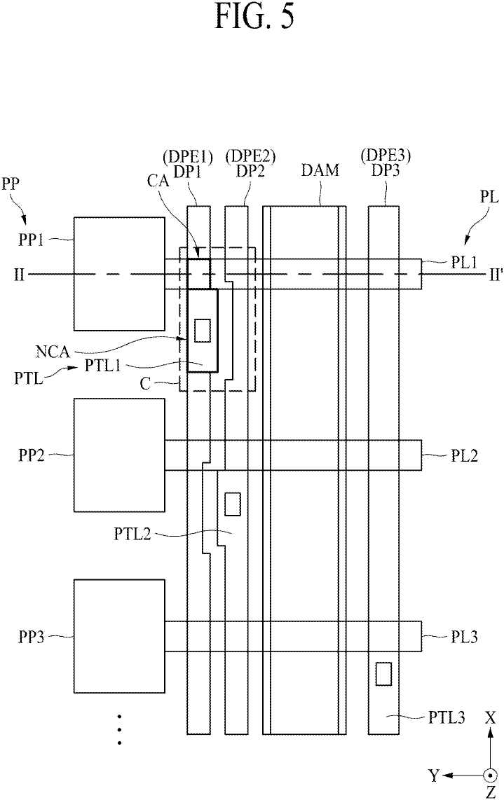

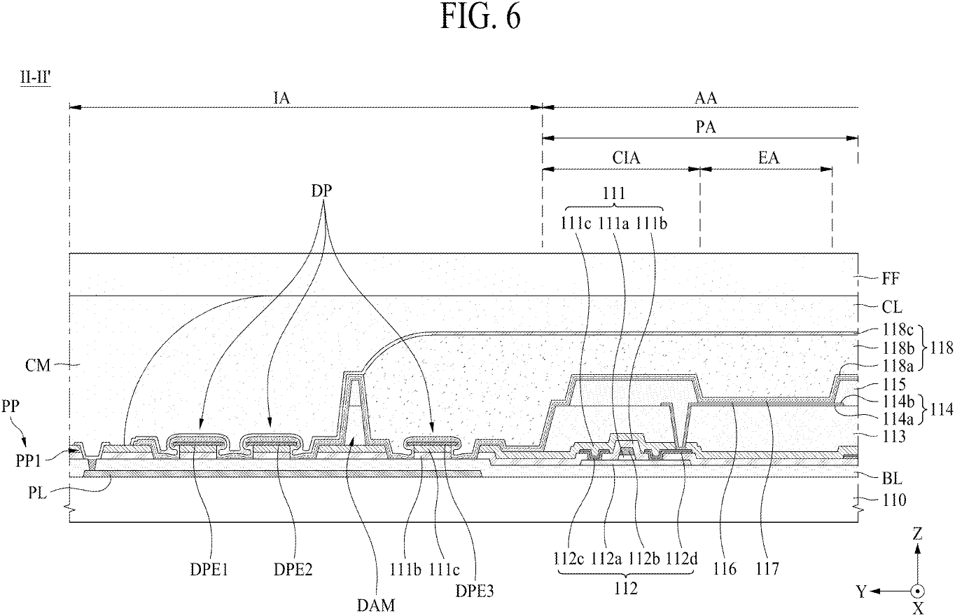

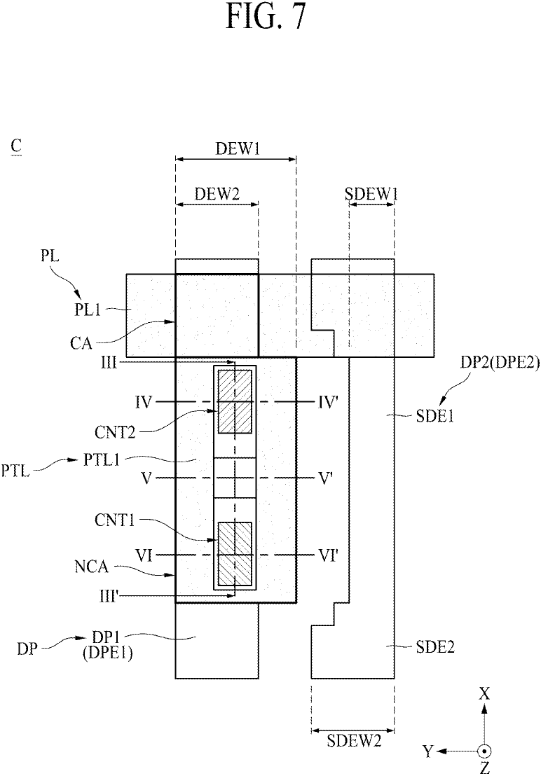

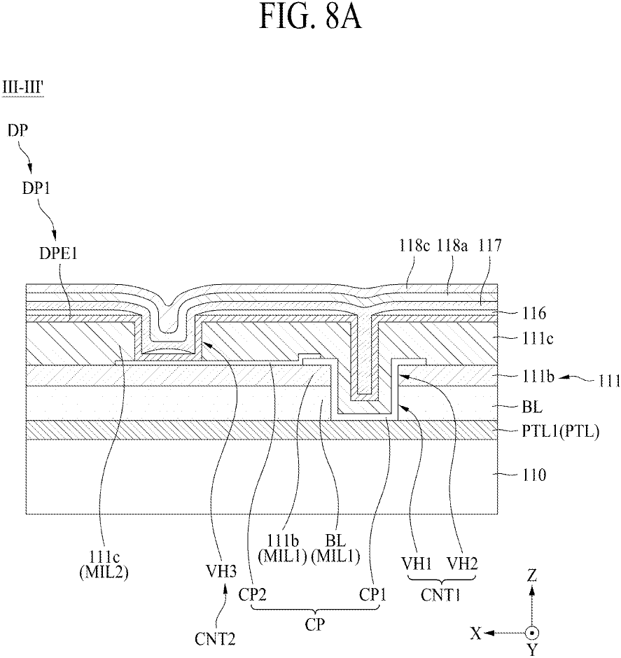

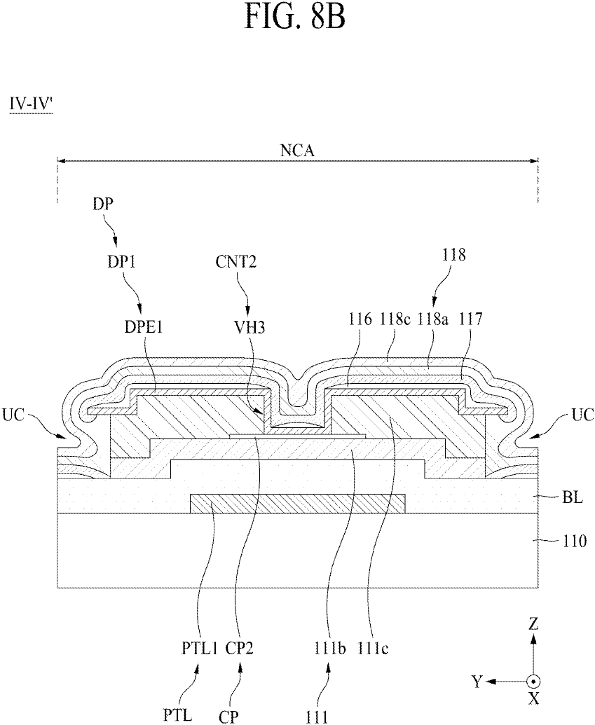

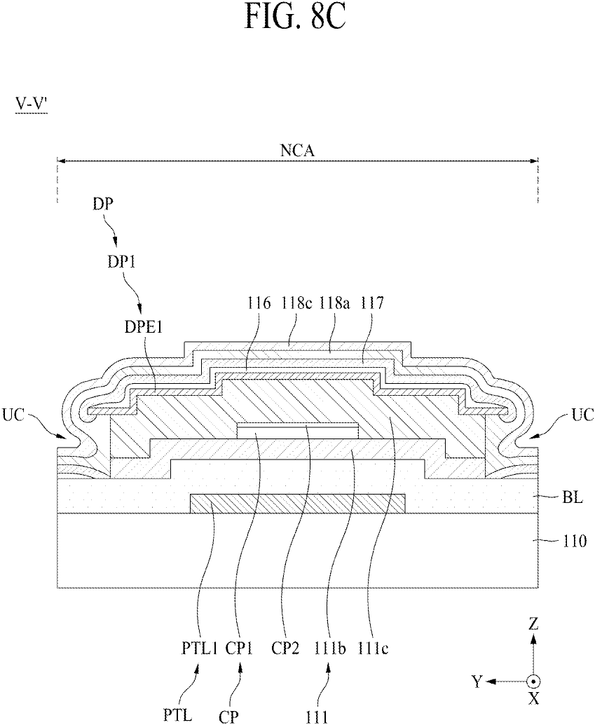

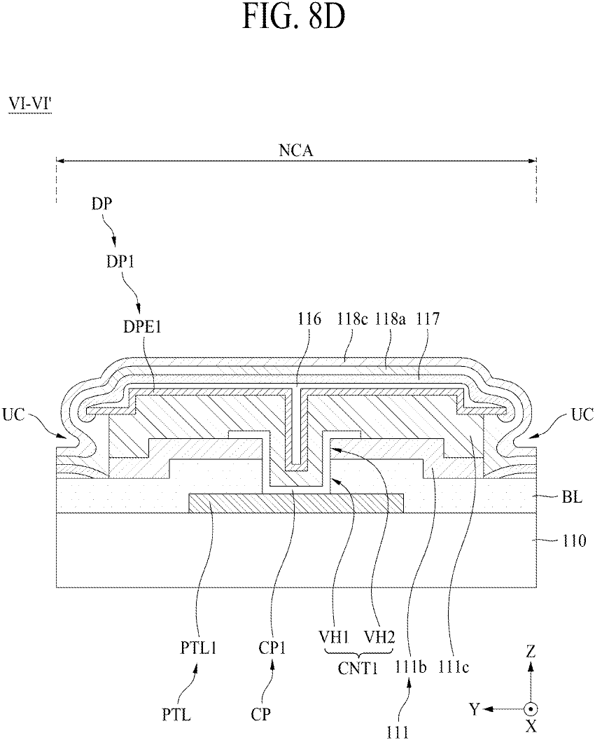

FIG. 5 is a view illustrating a display apparatus according to another embodiment of the present disclosure, FIG. 6 is a cross-sectional view taken along line II-II′ shown in FIG. 5, FIG. 7 is an enlarged view illustrating a portion C shown in FIG. 5, FIG. 8A is a cross-sectional view taken along line III-III′ shown in FIG. 7, FIG. 8B is a cross-sectional view taken along line IV-IV′ shown in FIG. 7, FIG. 8C is a cross-sectional view taken along line V-V′ shown in FIG. 7, and FIG. 8D is a cross-sectional view taken along line VI-VI′ shown in FIG. 7.

Referring to FIG. 5 to 8D, the display apparatus 100 according to another embodiment of the present disclosure is the same as the display apparatus 100 according to FIG. 2 except that the pad connection line PL further includes a protruded line PTL electrically connected thereto in a non-cross area NCA of the pad connection line PL, the protruded line PTL is protruded toward the non-cross area NCA, the connection portion CP electrically connects the dummy portion DP with the protruded line PTL on the protruded line PTL and the width of the dummy portion DP is changed. Therefore, the same reference numerals are given to the same elements, and the following description will be based on differences from FIG. 2.

In case of the display apparatus 100 according to FIG. 2, the connection portion CP is provided to electrically connect the dummy portion DP with the pad connection line PL in the cross area CA. Therefore, in case of the display apparatus 100 according to FIG. 2, the first contact hole CNT1 and the second contact hole CNT2 overlap each other in the thickness direction Z of the substrate 110 in the cross area CA.

In contrast, the display apparatus 100 according to FIG. 5 includes a non-cross area NCA adjacent to the cross area CA, in which the dummy portion DP and the pad connection line PL do not cross each other, and the connection portion CP is provided to electrically connect the dummy portion DP with the protruded line PTL on the protruded line PTL disposed in the non-cross area NCA.

As shown in FIG. 5, since the protruded line PTL and the dummy portion DP are provided in the non-cross area NCA to overlap each other in parallel without crossing each other, the non-cross area NCA may be distinguished from the cross area CA of FIG. 2, in which the pad connection line PL and the dummy portion DP cross each other in a cross shape.

In the display apparatus 100 according to FIG. 5, the connection portion CP is disposed in the non-cross area NCA to prevent the first connection line CP1 made of a metal material, such as Cu, from being damaged by a patterning material (or etching material) used in a patterning process for patterning the dummy portion DP (or dummy electrode DPE) and/or the pixel electrode 114. For example, the pixel electrode 114 or the dummy electrode DPE may be patterned by an etching material such as an Ag etchant. This is because that the first connection line CP1 may be etched and damaged by the Ag etchant when the first connection line CP1 made of a metal material such as Cu is disposed directly below the pixel electrode 114 or the dummy electrode DPE. On the other hand, the Ag etchant does not damage a transparent conductive material such as ITO. Therefore, in the display apparatus 100 according to FIG. 5, the first connection line CP1 made of a metal material such as Cu is positioned to be spaced apart from the pixel electrode 114 or the dummy electrode DPE as far as possible, and the first connection line CP1 is electrically connected to the dummy electrode DPE through the second connection line CP2 that is not damaged by the Ag etchant, so that the first connection line CP1 may be prevented from being damaged by the Ag etchant used during patterning of the dummy electrode DPE and the dummy portion DP may be electrically connected to the pad connection line PL. Meanwhile, in the case that the protruded line PTL that is in contact with the first connection line CP1 is made of Cu, since the protruded line PTL may be spaced apart from the pixel electrode 114 or the dummy electrode DPE as far as possible, the protruded line PTL may not be damaged by the Ag etchant.

In the display apparatus 100 according to another embodiment of the present disclosure, since the connection portion CP is not positioned in the cross area CA, a contact hole is not provided between the pad connection line PL and the dummy portion DP in the cross area CA as shown in the cross-sectional view of FIG. 6. On the pad connection line PL of the cross area CA, the interlayer insulating layer 111b on the buffer layer BL, the passivation layer 111c on the interlayer insulating layer 111b, and the dummy electrode DPE on the passivation layer 111c, which is wider than the passivation layer 111c, may be disposed. Therefore, the organic light emitting layer 116 (or the organic light emitting layer 116 and the common electrode 117) of the non-display portion IA may be disconnected in the undercut portion UC between the dummy portions, whereby moisture permeation into the display portion AA may be avoided.

Referring to FIG. 8A, the first middle insulating layer MIL1 according to another embodiment of the present disclosure may be disposed between the connection portion CP and the protruded line PTL. The first middle insulating layer MIL1 may include a buffer layer BL disposed on the protruded line PTL in the non-cross area NCA and an interlayer insulating layer 111b disposed on the buffer layer BL. In addition, the first middle insulating layer MIL1 may include a first contact hole CNT1 for connecting the connection portion CP with the protruded line PTL. In more detail, the first connection line CP1 of the connection portion CP may be electrically connected to the protruded line PTL through the first contact hole CNT1. The first connection line CP1 may be disposed in each of the first via hole VH1 passing through the buffer layer BL disposed on the protruded line PTL in the non-cross area NCA and the second via hole VH2 passing through the interlayer insulating layer 111b disposed on the first via hole VH1. Therefore, the first connection line CP1 is in contact with the upper surface of the protruded line PTL exposed from the first via hole VH1, and thus may be electrically connected to the protruded line PTL.

The second middle insulating layer MIL2 according to another embodiment of the present disclosure may be disposed between the dummy portion DP and the connection portion CP. The second middle insulating layer MIL2 may include a passivation layer 111c disposed on the interlayer insulating layer 111b in the non-cross area NCA. The second middle insulating layer MIL2 may include a second contact hole CNT2 for connecting the dummy portion DP with the connection portion CP (or the second connection line CP2). The dummy portion DP may be electrically connected to the second connection line CP2 through the second contact hole CNT2. The dummy portion DP (or the first dummy electrode DPE1) may be disposed in the third via hole VH3 passing through the passivation layer 111c disposed on the second via hole VH2 in the non-cross area NCA. Therefore, the dummy portion DP may be electrically connected to the second connection line CP2 by being in contact with the upper surface of the second connection line CP2 exposed from the third via hole VH3.

As shown in FIG. 8A, in the display apparatus 100 according to another embodiment of the present disclosure, in order to prevent the protruded line PTL of the pad connection line PL and/or the first connection line CP1 from being damaged by the Ag etchant, the first contact hole CNT1 may be disposed to be spaced apart from the second contact hole CNT2 on the protruded line PTL. Therefore, the first via hole VH1 and the second via hole VH2 of the first contact hole CNT1 may overlap each other in the thickness direction Z of the substrate 110, and the third via hole VH3 of the second contact hole CNT2 may not overlap the second via hole VH2 (or the first via hole VH1) in the thickness direction Z of the substrate 110.

As the first contact hole CNT1 and the second contact hole CNT2 are disposed to be spaced apart from each other, the first connection line CP1 may be extended between the first contact hole CNT1 and the second contact hole CNT2 by being in contact with the protruded line PTL in the first contact hole CNT1. That is, the first connection line CP1 may be extended from the first contact hole CNT1 to a space between the first contact hole CNT1 and the second contact hole CNT2.

The second connection line CP2 may be in contact with the upper surface and/or sides of the first connection line CP1 between the first contact hole CNT1 and the second contact hole CNT2, and may be in contact with a lower surface of the dummy portion DP (or the first dummy electrode DPE1) in the second contact hole CNT2 by being extended to the second contact hole CNT2.

Therefore, the display apparatus 100 according to another embodiment of the present disclosure is provided such that the dummy portion DP (or the first dummy electrode DPE1) and the protruded line PTL are connected to each other through the connection portion CP on the protruded line PTL disposed in the non-cross area NCA, whereby static electricity may be avoided, and the first connection line CP1 and/or the protruded line PTL may be prevented from being damaged by the Ag etchant to improve reliability.

Referring back to FIG. 5, in the display apparatus 100 according to another embodiment of the present disclosure, the first pad connection line PL1 may include a first protruded line PTL1 protruded toward the non-cross area NCA, and the second pad connection line PL2 may include a second protruded line PTL2 protruded toward the non-cross area NCA. In this case, the non-cross area NCA means an area in which the dummy portion DP and the pad connection line PL do not cross each other in a cross shape, and as shown in FIG. 5, the non-cross area NCA in which the first protruded line PTL1 is disposed and the non-cross area NCA in which the second protruded line PTL2 is disposed may be formed at their respective positions different from each other. Therefore, the display apparatus 100 according to another embodiment of the present disclosure may be provided such that the first protruded line PTL1 is disposed to be connected to the first pad connection line PL1 between the first pad connection line PL1 and the second pad connection line PL2 and the second protruded line PTL2 is disposed to be connected to the second pad connection line PL2 between the second pad connection line PL2 and the third pad connection line PL3.

The first dummy line DP1 may include a first dummy electrode DPE1 electrically connected to the first protruded line PTL1 on the first protruded line PTL1, and the second dummy line DP2 may include a second dummy electrode DPE2 electrically connected to the second protruded line PTL2 on the second protruded line PTL2. The third dummy line DP3 may include a third dummy electrode DPE3 electrically connected to the third protruded line PTL3 on the third protruded line PTL3. Since the first protruded line PTL1, the second protruded line PTL2 and the third protruded line PTL3 are disposed at different positions based on FIG. 5, the first dummy electrode DPE1, the second dummy electrode DPE2 and the third dummy electrode DPE3, which are electrically connected to the first protruded line PTL1, the second protruded line PTL2 and the third protruded line PTL3, may be disposed at different positions. Since FIG. 6 is a cross-sectional view along the pad connection line PL in which the protruded line PTL is not included, each of the first dummy electrode DPE1 of the first dummy line DP1, the second dummy electrode DPE2 of the second dummy line DP2 and the third dummy electrode DPE3 of the third dummy line DP3 may not be connected to the pad connection line PL in FIG. 6.

The display apparatus 100 according to another embodiment of the present disclosure may be provided such that the width of the dummy electrode overlapped with the non-cross area NCA is wider than that of the dummy electrode overlapped with the cross area CA.

For example, as shown in FIG. 7, the width DEW1 of the first dummy electrode overlapped with the first protruded line PTL1 may be wider than the width DEW2 of the first dummy electrode overlapped with the first pad connection line PL1 in the cross area CA or overlapped with the cross area CA. This is to make sure of a process margin of the protruded line PTL and the first connection line CP1, a process margin of the first connection line CP1 and the second connection line CP2 and a process margin of the second connection line CP2 and the dummy electrode DPE in a process of electrically connecting the dummy portion DP to the protruded line PTL through the connection portion CP. As the width (or area) of the first protruded line PTL1 is secured in the non-cross area NCA, even though a misalignment on the process occurs, the dummy electrode of the dummy portion DP may be electrically connected to the protruded line PTL through the connection portion CP and thus static electricity may be avoided.

Also, in the display apparatus 100 according to another embodiment of the present disclosure, as the dummy portion DP and the protruded line PTL are electrically connected to each other through the connection portion CP in the non-cross area NCA, more specifically the non-cross area NCA spaced apart from the cross area CA, parasitic capacitance with different signal lines disposed in a direction in parallel to the pad connection line PL may be avoided, whereby interference of the signal lines with an image signal may be avoided.

As shown in FIG. 7, the second dummy electrode DPE2 of the second dummy line DP2 may include a first sub-dummy electrode SDE1 disposed to face the first protruded line PTL1 in the second direction Y and a second sub-dummy electrode SDE2 connected to the first sub-dummy electrode SDE1. The second sub-dummy electrode SDE2 may be a second dummy electrode DPE2 that does not face the first protruded line PTL1 in the second direction Y.

A width SDEW1 of the first sub-dummy electrode SDE1 may be narrower than a width SDEW2 of the second sub-dummy electrode SDE2. As described above, the width of the dummy electrode DPE (or the first dummy electrode DPE1 or the first protruded line PTL1) of the non-cross area NCA may be formed to be larger than the width of the dummy electrode DPE of the cross area CA in order to make sure of the process margin. Therefore, an adjacent dummy electrode DPE (or the second dummy electrode DPE2 or the first sub-dummy electrode SDE1) disposed at a corresponding position of the dummy electrode DPE (or the first dummy electrode DPE1 or the first protruded line DPE1) of the non-cross area NCA may be formed to be narrow, and the width of the non-display portion IA (or the edge portion or bezel of the substrate 110) may be reduced or minimized. As a result, when the plurality of display apparatuses 100 are disposed in the form of a multi-screen, an image having no sense of disconnection may be implemented.

As shown in FIGS. 8B to 8D, in the display apparatus 100 according to another embodiment of the present disclosure, the protruded line PTL may be connected with the dummy electrode DPE of the dummy portion DP in the non-cross area NCA, and the undercut portion UC may be formed through the dummy electrode DPE disposed in the non-cross area NCA to disconnect the organic light emitting layer 116.

Referring to FIG. 8B, the protruded line PTL on the substrate 110, the buffer layer BL disposed on the protruded line PTL to cover the protruded line PTL, the interlayer insulating layer 111b on the buffer layer BL, the second connection line CP2 on the interlayer insulating layer 111b, a second contact hole CNT2 having a third via hole VH3 formed by passing through the passivation layer 111c to expose a portion of the second connection line CP2, and the dummy portion DP (or the first dummy line DP1 or the first dummy electrode DPE1) that is in contact with the second connection line CP2 in the second contact hole CNT2 and provided to be wider than the passivation layer 111c while covering the upper surface of the passivation layer 111c may be disposed in a portion of one side of the protruded line PTL formed to be connected to the pad connection line PL in the non-cross area NCA.

Therefore, the dummy portion DP disposed in the non-cross area NCA may be electrically connected to the second connection line CP2, and the organic light emitting layer 116 disposed at the edge portion of the substrate 110 may be disconnected by the undercut portion UC formed at both sides of the dummy portion DP. The common electrode 117 disposed on the organic light emitting layer 116 may be disconnected or not in the undercut portion UC.

Referring to FIG. 8C, the protruded line PTL disposed on the substrate 110, the buffer layer BL disposed on the protruded line PTL to cover the protruded line PTL, the interlayer insulating layer 111b on the buffer layer BL, the first connection line CP1 on the interlayer insulating layer 111b, the second connection line CP2 that is in contact with the upper surface of the first connection line CP1, the passivation layer 111c disposed to cover the upper surface and sides of the second connection line CP2 and the sides of the first connection line CP1, and the dummy portion DP (or the first dummy line DP1 or the first dummy electrode DPE1) provided to be wider than the passivation layer 111c while covering the upper surface of the passivation layer 111c may be disposed between the first contact hole CNT1 and the second contact hole CNT2 in the non-cross area NCA.

Therefore, the first connection line CP1 and the second connection line CP2 may be electrically connected to each other between the first contact hole CNT1 and the second contact hole CNT2 of the non-cross area NCA, and the organic light emitting layer 116 may be disconnected by the undercut portion UC formed at both sides of the dummy portion DP. The common electrode 117 disposed on the organic light emitting layer 116 may be disconnected or not in the undercut portion UC.

Referring to FIG. 8D, the protruded line PTL disposed on the substrate 110, the first via hole VH1 formed by passing through the buffer layer BL disposed on the protruded line PTL to cover a portion of the protruded line PTL, the second via hole VH2 formed by passing through the interlayer insulating layer 111b disposed on the first via hole VH1, the first connection line CP1 that is in contact with the upper surface of the protruded line PTL through the first contact hole CNT1 where the first via hole VH1 and the second via hole VH2 overlap each other and covers the upper surface of the interlayer insulating layer 111b, the passivation layer 111c that is in contact with the upper surface of the interlayer insulating layer 111b while covering the upper surface of the first connection line CP1, and the dummy portion DP (or the first dummy line DP1 or the first dummy electrode DPE1) provided to be wider than the passivation layer 111c while covering the upper surface of the passivation layer 111c may be disposed in a portion (or end of the protruded line PTL) of the other side of the protruded line PTL in the non-cross area NCA. In this case, the dummy portion DP may be provided in the first contact hole CNT1 to have a concave shape along a profile of the passivation layer 111c concavely inserted in the first contact hole CNT1.

Therefore, the first connection line CP1 disposed at a portion of the other side of the protruded line PTL in the non-cross area NCA may be electrically connected to the protruded line PTL. The organic light emitting layer 116 disposed at the edge portion of the substrate 110 may be disconnected by the undercut portion UC formed at both sides of the dummy portion DP. The common electrode 117 disposed on the organic light emitting layer 116 may be disconnected or not in the undercut portion UC.

As a result, the display apparatus 100 according to another embodiment of the present disclosure may obtain the following effects.

First, in the display apparatus 100 according to another embodiment of the present disclosure, the organic light emitting layer 116 is disconnected by the dummy portion DP disposed inside the non-cross area NCA or on the protruded line PTL at the edge portion of the substrate 110, so that moisture permeation into the display portion AA may be avoided, whereby reliability of the light emitting element may be improved.

Second, in the display apparatus 100 according to another embodiment of the present disclosure, the dummy electrode of the dummy portion DP is electrically connected to the protruded line PTL through the connection portion CP in the non-cross area NCA disposed at the edge portion of the substrate 110, whereby defects due to static electricity may be avoided.

Third, in the display apparatus 100 according to another embodiment of the present disclosure, the first contact hole CNT1 and the second contact hole CNT2 are disposed to be spaced apart from each other in the non-cross area NCA, so that the first connection line CP1 and/or the protruded line PTL may be prevented from being damaged by the etching material (or patterning material), such as Ag etchant used during patterning of the dummy portion DP (or the pixel electrode 114), whereby reliability and lifespan may be improved.

Fourth, in the display apparatus according to another embodiment of the present disclosure, the width of the dummy portion DP overlapped with the protruded line PTL and the width of the dummy portion DP that is not overlapped with the protruded line PTL is different from each other in the non-cross area NCA, whereby the process margin of the dummy portion DP and the protruded line PTL may be secured and the width at the edge portion of the substrate 110 may be reduced. Therefore, when the plurality of display apparatuses 100 are disposed in the form of a multi-screen, an image having no sense of disconnection may be implemented.

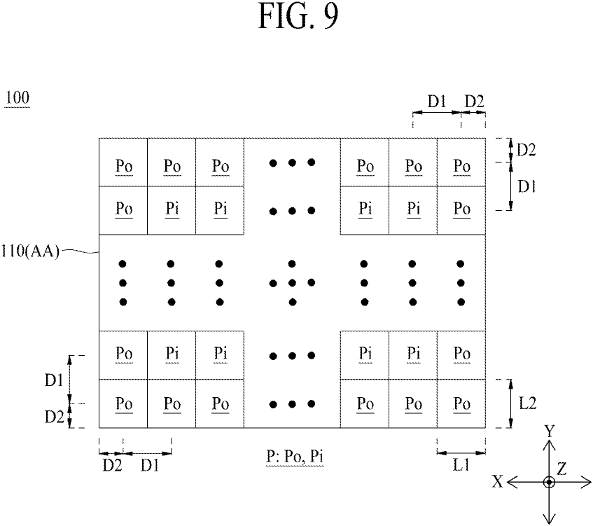

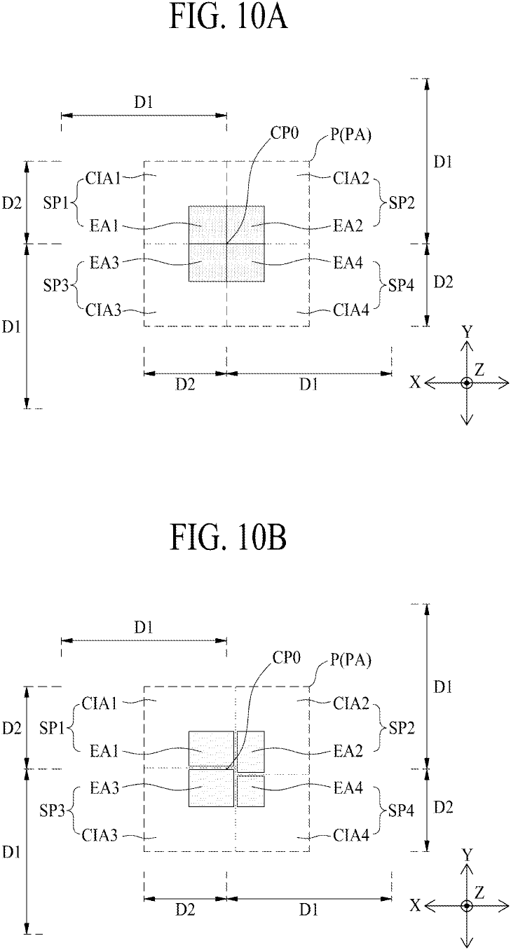

FIG. 9 is a schematic front view illustrating a display apparatus according to one embodiment of the present disclosure, FIG. 10A is a view illustrating one subpixel according to one example shown in FIG. 9, and FIG. 10B is a view illustrating one subpixel according to another example shown in FIG. 9.

Referring to FIG. 9, in the display apparatus 100 according to one embodiment of the present disclosure, the display panel may include a substrate 110 having a display portion AA, and a plurality of pixels P formed on the display portion AA of the substrate 110.

The display portion AA may be expressed as an area where an image is displayed and may be expressed as an active portion, an active region, or a display region. A size of the display portion AA may be the same as the size of the substrate 110(or display apparatus). Accordingly, the display portion AA is implemented (or disposed) on the entire front surface of the substrate 110 so that the substrate 110 does not include a non-display region which is provided along the edge of the substrate 110 to surround the entire display portion AA. Accordingly, the entire front surface of the display apparatus may implement the display portion AA.

The end (or outermost) of the display portion AA may be aligned with the outer surface of the substrate 110. For example, based on the thickness direction (Z or third direction) of the display apparatus, the lateral surface of the display portion AA may be aligned with an extended vertical extension line perpendicular to the outer surface of the substrate 110. The lateral surface of the display portion AA may be surrounded only by air without being surrounded by a separate mechanism. That is, all of the lateral surfaces of the display portion AA may have a structure in direct contact with air without being surrounded by a separate mechanism. Accordingly, since the outer surface of the substrate 110 corresponding to the end of the display portion AA is surrounded only by air, the display apparatus 100 according to the embodiment of the present disclosure may have an air-bezel structure in which the end (or the lateral surface) of the display portion AA is surrounded by air instead of an opaque non-display region or a structure without a bezel.

The plurality of pixels P may be arranged (or disposed) to have a first interval D1 on the display portion AA of the substrate 110 in each of the first direction (X) and the second direction (Y). The first direction (X) may be a horizontal direction, or a first longitudinal direction (e.g., a horizontal longitudinal direction) of the substrate 110 or the display apparatus. The second direction (Y) may be a vertical direction or may be a second longitudinal direction (e.g., a vertical longitudinal direction) of the substrate 110 or the display apparatus.

Since the plurality of pixels P may be arranged to have the first interval D1, the dummy portion DP, the pad portion PP, the connection portion CP and the dam DAM may be disposed at a position included in the first interval D1 without being overlapped with the subpixels SP1, SP2, SP3 and SP4. For example, based on FIG. 10A, the dummy portion DP, the pad portion PP, the connection portion CP and the dam DAM may be spaced apart from one another at a predetermined distance at a left side of the first subpixel SP 1 within the range of half of the first interval D1. The pad portion PP according to another example may be provided to be disposed on a rear surface (or back surface) of the substrate 110, and when the gate driver GD is provided, the gate driver GD may be implemented (or embedded) in an entire surface (or upper surface) of the substrate 110.

Each of the plurality of pixels P may be implemented on each of a plurality of pixel regions defined on the display portion AA of the substrate 110. Each of the plurality of pixel regions may have a first length L1 parallel to the first direction (X) and a second length L2 parallel to the second direction (Y). The first length L1 may be equal to the second length L2 or may be equal to the first interval D1. Each of the first length L1 and the second length L2 may be equal to the first interval D1. Accordingly, the plurality of pixels P may all have the same size. For example, the first length L1 may be expressed as a first width, a horizontal length, or a horizontal width. The second length L2 may be expressed as a second width, a vertical length, or a vertical width.

Two pixels P adjacent in each of the first direction (X) and the second direction (Y) may have the same first interval D1 within an error range in the manufacturing process. The first interval D1 may be a pitch (or pixel pitch) between two adjacent pixels P. For example, the first interval D1 may be the shortest distance (or the shortest length) between the centers of each of the two adjacent pixels P. Optionally, the pixel pitch may be a size between one end and the other end of the pixel P parallel to the first direction (X). Also, in another example, the pixel pitch may be expressed as a size between one end and the other end of the pixel P parallel to the second direction (Y).

Each of the plurality of pixels P may include a circuit layer including a pixel circuit implemented in a pixel region on the substrate 110 and a light emitting device layer disposed on the circuit layer and connected to the pixel circuit. The pixel circuit outputs a data current corresponding to a data signal in response to the data signal and a scan signal supplied from pixel driving lines disposed in the pixel region. The light emitting device layer may include a light emitting layer that emits light by the data current supplied from the pixel circuit.

The plurality of pixels P may be divided into outermost pixels Po and internal pixels Pi.

The outermost pixels Po (or the first pixels) may be pixels disposed closest to the dam DAM or the outer surface of the substrate 110 among the plurality of pixels P. For example, the outermost pixels Po may be expressed as first pixels. The outermost pixels Po may include at least one dummy portion, the pad portion and the connection portion.

The second interval D2 between the central portion of the outermost pixels Po and the outer surface or outer side of the substrate 110 may be half or less than half the first interval D1. For example, the second interval D2 may be the shortest distance (or the shortest length) between the center of the outermost pixels Po and the outer surface of the substrate 110.

When the second interval D2 exceeds half of the first interval D1, the substrate 110 have a larger size than the display portion AA by a difference between the half of the first interval D1 and the second interval D2., and therefore, the region between the end of the outermost pixel Po and the outer surface of the substrate 110 may be configured as a non-display region surrounding the entire display portion AA. For example, when the second interval D2 exceeds half of the first interval D1, the substrate 110 inevitably includes a bezel region according to the non-display region surrounding the entire display portion AA. Therefore, when the plurality of display apparatuses 100 are disposed adjacent to each other, the sum of the second intervals D2 of each of two the substrates 110 is greater than the first interval D1, so that the sum (or seam) of the bezel region of each the substrate 110 may be recognized by the user.

Meanwhile, when the second interval D2 is half or less than half the first interval D1, the end of the outermost pixel Po may be aligned with the outer surface of the substrate 110 or the end or sides of the display portion AA may be aligned with the outer surface or outer side of the substrate 110, and thus the display portion AA may be implemented (or disposed) on the entire surface of the substrate 110. Accordingly, even if a plurality of display apparatuses 100 according to an embodiment of the present disclosure are disposed adjacently, a seam may not be recognized by a user.

The internal pixels Pi may be pixels other than the outermost pixels Po among the plurality of pixels P or pixels surrounded by the outermost pixels Po among the plurality of pixels P. The internal pixels Pi may be represented by second pixels. These internal pixels Pi may be implemented in a configuration or structure different from that of the outermost pixel Po.

Referring to FIGS. 9 and 10A, one pixel P according to an embodiment of the present disclosure may include first to fourth sub-pixels SP1, SP2, SP3, and SP4 disposed in the pixel region PA.

The first sub-pixel SP1 may be disposed in a first sub-pixel region of the pixel region PA, the second sub-pixel SP2 may be disposed in a second sub-pixel region of the pixel region PA, the third subpixel SP3 may be disposed in a third subpixel region of the pixel region PA, and the fourth subpixel SP4 may be disposed in a fourth subpixel region of the pixel region PA.

As an example, the first subpixel SP1 may be implemented to emit light of a first color, the second subpixel SP2 may be implemented to emit light of a second color, the third subpixel SP3 may be implemented to emit light of a third color, and the fourth sub-pixel SP4 may be implemented to emit light of the fourth color. Each of the first to fourth colors may be different. For example, the first color may be red, the second color may be blue, the third color may be white, and the fourth color may be green.

As another example, some of the first to fourth colors may be the same. For example, the first color may be red, the second color may be first green, the third color may be second green, and the fourth color may be blue.

Each of the first to fourth sub-pixels SP1, SP2, SP3, and SP4 may include light emitting region EA1, EA2, EA3, and EA4 and circuit regions CIA1, CIA2, CIA3, and CIA4.

The light emitting regions EA1, EA2, EA3, and EA4 may be disposed to be shifted toward the central portion CP0 of the pixel P in the sub-pixel region. For example, the light emitting regions EA1, EA2, EA3, and EA4 may be expressed as an opening region, an opening, or a light emitting portion.

According to an example, the respective light emitting regions EA1, EA2, EA3, and EA4 of each of the first to fourth sub-pixels SP1, SP2, SP3, and SP4 may have the same size. For example, each of the light emitting regions EA1, EA2, EA3, and EA4 of the first to fourth subpixels SP1, SP2, SP3, and SP4 may have a uniform quad structure or a uniform stripe structure. For example, the light emitting regions EA1, EA2, EA3, and EA4 having a uniform quad structure or a uniform stripe structure may have a size smaller than a quadrant size of the pixel P and may be disposed to be shifted toward the central portion CP0 in the sub-pixel region or may be disposed to be concentrated in the central portion CP0 of the pixel P.

Referring to FIGS. 9 and 10B, the respective light emitting regions EA1, EA2, EA3, and EA4 of each of the first to fourth subpixels SP1, SP2, SP3, and SP4 according to another example may have different sizes. For example, each of the light emitting regions EA1, EA2, EA3, and EA4 of the first to fourth subpixels SP1, SP2, SP3, and SP4 may have a non-uniform quad structure or a non-uniform stripe structure.

The size of each of the first to fourth sub-pixels SP1, SP2, SP3, and SP4 having a non-uniform quad structure (or a non-uniform stripe structure) may be set according to resolution, luminous efficiency, or image quality. As an example, when the light emitting regions EA1, EA2, EA3, and EA4 have an unequal quad structure (or unequal stripe structure), the light emitting region EA4 of the fourth subpixel SP4, among the respective light emitting regions EA1, EA2, EA3, and EA4 of each of the first to fourth subpixels SP1, SP2, SP3, and SP4 may have the smallest size, and the light emitting region EA3 of the third subpixel SP3 may have the largest size. For example, the light emitting regions EA1, EA2, EA3, and EA4 having a non-uniform quad structure (or a non-uniform stripe structure) may be concentrated around the central portion CP0 of one pixel P. In one pixel P (or pixel region PA), the central portions of the light emitting regions EA1, EA2, EA3, and EA4 are aligned with the central portion CP0 of the pixel P or spaced apart from the central portion CP0 of the pixel P.

The respective circuit regions CIA1, CIA2, CIA3, and CIA4 of each of the first to fourth sub-pixels SP1, SP2, SP3, and SP4 may be disposed around the corresponding light emitting regions EA1, EA2, EA3, and EA4. The circuit regions CIA1, CIA2, CIA3, and CIA4 may include a circuit for emitting a corresponding sub-pixel and pixel driving lines. For example, the circuit regions CIA1, CIA2, CIA3, and CIA4 may be expressed as a non-light-emitting region, a non-opening region, a non-light-emitting portion, a non-opening portion, or a peripheral portion.

Alternatively, in order to increase an aperture ratio of the sub-pixels SP1, SP2, SP3, and SP4 corresponding to the size of the light emitting regions EA1, EA2, EA3, and EA4 or to reduce a pixel pitch D1 according to high resolution of the pixel P, the respective light emitting regions EA1, EA2, EA3, and EA4 of each of the first to fourth sub-pixels SP1, SP2, SP3, and SP4 may be extended onto the circuit regions CIA1, CIA2, CIA3, and CIA4 so as to overlap some or all of the circuit regions CIA1, CIA2, CIA3, and CIA4. For example, the respective light emitting regions EA1, EA2, EA3, and EA4 of each of the first to fourth subpixels SP1, SP2, SP3 and SP4 may be implemented on the substrate 110 to overlap the corresponding circuit regions CIA1, CIA2, CIA3, and CIA4. In this case, the light emitting regions EA1, EA2, EA3, and EA4 may have a size which is the same as or larger than the circuit regions CIA1, CIA2, CIA3, and CIA4.

Alternatively, each of the plurality of pixels P according to another example may include first to third sub-pixels SP1, SP2, and SP3.

The respective light emitting regions EA1, EA2, and EA3 of each of the first to third sub-pixels SP1, SP2, and SP3 may have a rectangular shape having a shorter side parallel to the first direction (X) and a longer side parallel to the second direction (Y) and may be arranged, for example, in a 1x3 shape or a 1x3 stripe shape. For example, the first subpixel SP1 may be a red subpixel, the second subpixel SP2 may be a blue subpixel, and the third subpixel SP3 may be a green subpixel.

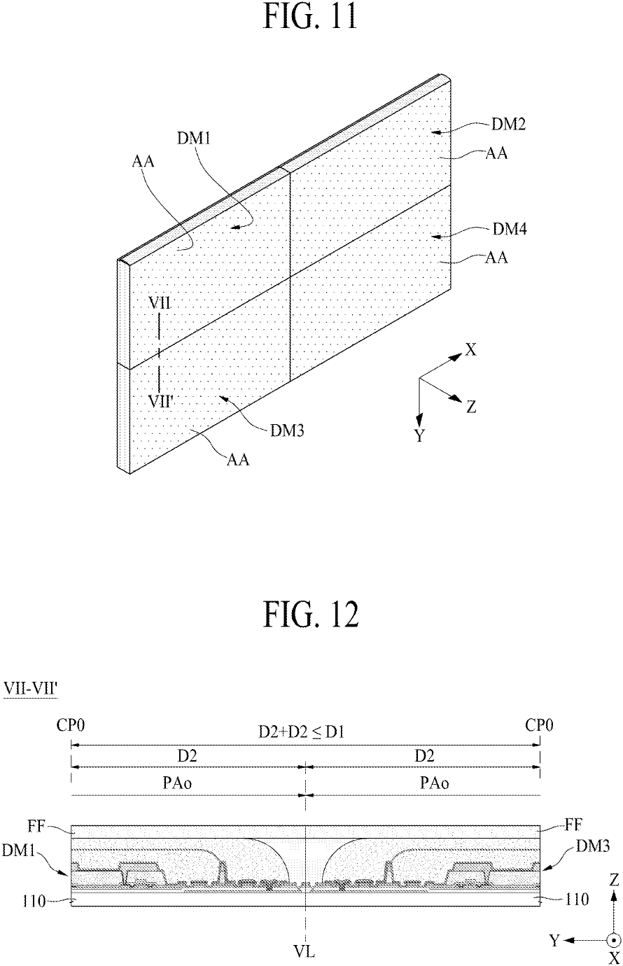

FIG. 11 is a view illustrating a multi-screen display apparatus according to one embodiment of the present disclosure, and FIG. 12 is a cross-sectional view taken along line VII-VII′ shown in FIG. 11, illustrating a multi-screen display apparatus implemented by tiling the display apparatus according to another embodiment of the present disclosure shown in FIG. 9 to 10B.

Referring to FIGS. 11 and 12, the multi-screen display apparatus according to one embodiment of the present disclosure may include a plurality of display modules DM1, DM2, DM3 and DM4.

Each of the plurality of display modules DM1, DM2, DM3 and DM4 may display an individual image or divisionally display one image. Each of the plurality of display modules DM1, DM2, DM3 and DM4 includes the display apparatus according to another embodiment of the present disclosure shown in FIG. 9 to 10B, and a repeated description thereof will be omitted.

Each of the plurality of display modules DM1, DM2, DM3 and DM4 may be tiled in a separate tiling frame such that their sides are in contact with each other. For example, each of the plurality of display modules DM1, DM2, DM3 and DM4 may be tiled to have a shape of N X M (N is a positive integer of 2 or more and M is a positive integer of 2 or more), whereby a multi-screen display apparatus of a large screen may be implemented.

Each of the plurality of display modules DM1, DM2, DM3 and DM4 does not include a bezel area (or non-display area) surrounding the entire display portion AA in which an image is displayed, and has an air-bezel structure in which the display portion AA is surrounded by the air. That is, in each of the plurality of display modules DM1, DM2, DM3 and DM4, the entire front surface (or upper surface) of the substrate 110 is implemented as the display portion AA.

According to the present embodiment, in each of the plurality of display modules DM1, DM2, DM3 and DM4, a second interval D2 between a central portion CP0 of an outermost pixel Po (or outermost pixel region PAo) and an outermost outer side of the substrate 110 is implemented as a half or less of the first interval D1 between adjacent pixels. Therefore, in two adjacent display modules DM1, DM2, DM3 and DM4, in which sides are connected with (or in contact with) each other along the first direction X and the second direction Y in accordance with a side coupling method, an interval D2+D2 between adjacent outermost pixels Po (or outermost pixel region PAo) is the same as or smaller than the first interval D1 between two adjacent pixels.

In the example of FIG. 12, in the first display module DM1 and the third display module DM3, in which sides are connected with (or in contact with) each other along the second direction Y, the interval D2+D2 between the central portion CP0 of the outermost pixel Po (or outermost pixel region PAo) of the first display module DM1 and the central portion CP0 of the outermost pixel Po (or outermost pixel region PAo) of the third display module DM3 may be the same as or smaller than the first interval D1 between two adjacent pixels respectively disposed in the first display module DM1 and the third display module DM3.

Therefore, since the interval D2+D2 between the central portions CP0 of the outermost pixels Po (or outermost pixel region PAo) of two adjacent display modules DM1, DM2, DM3 and DM4 in which sides are connected with (or in contact with) each other along the first direction X and the second direction Y are the same as or smaller than the first interval D1 between two adjacent pixels respectively disposed in the display modules DM1, DM2, DM3 and DM4, there is no boundary portion or seam between two adjacent display modules DM1, DM2, DM3 and DM4, whereby a dark portion due to the boundary portion provided between the plurality of display modules DM1, DM2, DM3 and DM4 does not exist. As a result, the image displayed on the multi-screen display apparatus, in which each of the plurality of display modules DM1, DM2, DM3 and DM4 is tiled in the form of 2X2, may be displayed continuously without disconnection (or discontinuity) in the boundary portion between the plurality of display modules DM1, DM2, DM3 and DM4.

In FIGS. 11 and 12, the plurality of display modules DM1, DM2, DM3 and DM4 may be tiled to have a 2X2 shape, but are not limited thereto, and the plurality of display modules DM1, DM2, DM3 and DM4 may be tiled to have a shape of xX1, a shape of 1Xy or a shape of xXy, wherein x may be a natural number of 2 or more, which is equal to y, and y may be a natural number of 2 or more, which is greater than or smaller than x.

As described above, in the multi-screen display apparatus according to the present disclosure, when the display portion AA of each of the plurality of display modules DM1, DM2, DM3 and DM4 is displayed as a single image on one screen, an image continuously connected without being disconnected in the boundary portion between the plurality of display modules DM1, DM2, DM3 and DM4 may be displayed. As a result, image immersion of a viewer who views an image displayed on the multi-screen display apparatus may be improved.

The display apparatus and the multi-screen display apparatus including the same according to the present disclosure may be described as follows.

The display apparatus according to some embodiments of the present disclosure may include a substrate having a display portion, a plurality of pixels disposed in the display portion, pad portions spaced apart from the plurality of pixels and disposed at an edge portion of one side of the substrate, a dummy portion surrounding the display portion and disposed between the pad portion and the plurality of pixels, a pad connection line crossing the dummy portion and connected to each of the pad portions, and a connection portion electrically connecting the dummy portion with the pad connection line.

The display apparatus according to some embodiments of the present disclosure may include a cross area where the dummy portion and the pad connection line cross each other, wherein the connection portion may electrically connect the dummy portion with the pad connection line in the cross area.

The display apparatus according to some embodiments of the present disclosure may include a first middle insulating layer disposed between the connection portion and the pad connection line, and a second middle insulating layer disposed between the dummy portion and the connection portion, wherein the first middle insulating layer may include a first contact hole for connecting the connection portion with the pad connection line, the second middle insulating layer may include a second contact hole for connecting the dummy portion with the connection portion, and the first contact hole may overlap the second contact hole in the cross area.

According to some embodiments of the present disclosure, the connection portion may be electrically connected to the pad connection line through the first contact hole, and the dummy portion may be electrically connected to the connection portion through the second contact hole.

According to some embodiments of the present disclosure, the first middle insulating layer may include a buffer layer disposed on the pad connection line and an interlayer insulating layer disposed on the buffer layer, the second middle insulating layer may include a passivation layer disposed on the interlayer insulating layer, the first contact hole may include a first via hole passing through the buffer layer disposed on the pad connection line and a second via hole passing through the interlayer insulating layer disposed on the first via hole, the second contact hole may include a third via hole passing through the passivation layer disposed on the second via hole, the connection portion may be electrically connected to the pad connection line through the first via hole and the second via hole, and the dummy portion may be electrically connected to the connection portion through the third via hole.

The display apparatus according to some embodiments of the present disclosure may include a dam disposed at an edge portion of the substrate to surround the display portion, and a light emitting element layer including an organic light emitting layer disposed on the display portion and the dam and a common electrode disposed on the organic light emitting layer, wherein each of the organic light emitting layer and the common electrode may be disconnected by the dummy portion.

According to some embodiments of the present disclosure, the dummy portion may include a first dummy line disposed between the pad portion and the dam and a second dummy line disposed between the first dummy line and the dam, the pad portion may include a first pad member and a second pad member, which are disposed to be spaced apart from each other at the edge portion of the substrate, the pad connection line may include a first pad connection line connected to the first pad member and a second pad connection line connected to the second pad member, the first dummy line may include a first dummy electrode electrically connected to the first pad connection line while crossing the first pad connection line, and the second dummy line may include a second dummy electrode electrically connected to the second pad connection line while crossing the second pad connection line.

The display apparatus according to some embodiments of the present disclosure may include a buffer layer disposed on the pad connection line, an interlayer insulating layer disposed on the buffer layer, and a passivation layer disposed between the interlayer insulating layer and the first dummy electrode, wherein a width of the first dummy electrode may be wider than that of the passivation layer.

The display apparatus according to some embodiments of the present disclosure may include an undercut portion disposed between the first dummy line and the second dummy line, wherein the undercut portion may be disposed along the first dummy line or the second dummy line.

According to some embodiments of the present disclosure, the dummy portion may include a third dummy line disposed between the dam and the display portion, the pad portion may include a third pad member spaced apart from the second pad member at the edge portion of the substrate, the pad connection line may include a third pad connection line connected to the third pad member, the third dummy line may include a third dummy electrode electrically connected to the third pad connection line while crossing the third pad connection line, and a width of the third dummy electrode may be the same as or wider than that of the first dummy electrode.

The display apparatus according to some embodiments of the present disclosure may include a cross area where the dummy portion and the pad connection line cross each other, and a non-cross area adjacent to the cross area, in which the dummy portion and the pad connection line do not cross each other, wherein the pad connection line may include a protruded line protruded toward the non-cross area, and the connection portion may electrically connect the dummy portion with the protruded line on the protruded line.

The display apparatus according to some embodiments of the present disclosure may include a first middle insulating layer disposed between the connection portion and the protruded line, and a second middle insulating layer disposed between the dummy portion and the connection portion, wherein the first middle insulating layer may include a first contact hole for connecting the connection portion with the protruded line, the second middle insulating layer may include a second contact hole for connecting the dummy portion with the connection portion, and the first contact hole may be disposed to be spaced apart from the second contact hole on the protruded line.

According to some embodiments of the present disclosure, the connection portion may include a first connection line that is in contact with the protruded line and extended from the first contact hole to a space between the first contact hole and the second contact hole, and a second connection line connected to the first connection line and extended to the second contact line to be in contact with the dummy portion, and the first connection line may be in contact with the second connection line between the first contact hole and the second contact hole.

According to some embodiments of the present disclosure, the first middle insulating layer may include a buffer layer disposed on the protruded line and an interlayer insulating layer disposed on the buffer layer, the second middle insulating layer may include a passivation layer disposed on the interlayer insulating layer, the first contact hole may include a first via hole passing through the buffer layer and a second via hole passing through the interlayer insulating layer disposed on the first via hole, the second contact hole may include a third via hole passing through the passivation layer disposed on the second via hole, the first via hole may overlap the second via hole, and the third via hole may not overlap the second via hole.

The display apparatus according to some embodiments of the present disclosure may include a dam disposed at the edge portion of the substrate to surround the display portion, wherein the dummy portion may include a first dummy line disposed between the pad portion and the dam and a second dummy line disposed between the first dummy line and the dam, the pad portion may include a first pad member and a second pad member, which are disposed to be spaced apart from each other at an edge portion of the substrate, the pad connection line may include a first pad connection line connected to the first pad member and a second pad connection line connected to the second pad member, the first pad connection line may include a first protruded line protruded toward the non-cross area, the second pad connection line may include a second protruded line protruded toward the non-cross area, the first dummy line may include a first dummy electrode electrically connected to the first protruded line on the first protruded line, and the second dummy line may include a second dummy electrode electrically connected to the second protruded line on the second protruded line.

According to some embodiments of the present disclosure, the pad portion may include a third pad member spaced apart from the second pad member at the edge portion of the substrate, the pad connection line may include a third pad connection line connected to the third pad member, the first protruded line may be disposed between the first pad connection line and the second pad connection line, and the second protruded line may be disposed between the second pad connection line and the third pad connection line.

According to some embodiments of the present disclosure, a width of the first dummy electrode overlapped with the first protruded line may be wider than that of the first dummy electrode overlapped with the cross area.

According to some embodiments of the present disclosure, the second dummy electrode may include a first sub-dummy electrode disposed to face the first protruded line and a second sub-dummy electrode connected to the first sub-dummy electrode, and a width of the first sub-dummy electrode may be narrower than that of the second sub-dummy electrode.

According to some embodiments of the present disclosure, sides of the display portion may be aligned on an outer side of the substrate or a size of the display portion may be the same as that of the substrate.

According to some embodiments of the present disclosure, an outermost pixel of the plurality of pixels may include at least one dummy portion, the pad portion and the connection portion, or the plurality of pixels may be disposed on the substrate to have a pixel pitch along a first direction and a second direction crossing the first direction, and an interval between a central portion of the outermost pixel and the outer side of the substrate may be a half or less of the pixel pitch.

The display apparatus according to one embodiment of the present disclosure may be applied to all of electronic devices that include a display panel. For example, the display apparatus according to the present disclosure may be applied to a mobile device, a video phone, a smart watch, a watch phone, a wearable device, a foldable device, a rollable device, a bendable device, a flexible device, a curved device, an electronic diary, electronic book, a portable multimedia player (PMP), a personal digital assistant (PDA), an MP3 player, a mobile medical device, a desktop PC, a laptop PC, a netbook computer, a workstation, a navigator, a vehicle navigator, a vehicle display device, a television, a wall paper display device, a signage device, a game device, a notebook computer, a monitor, a camera, a camcorder, home appliances, etc.

According to the present disclosure, the following advantageous effects may be obtained.

According to some embodiments of the present disclosure, the display apparatus, which may prevent deterioration in reliability of a light emitting element due to moisture permeation from occurring, and the multi-screen display apparatus including the same may be provided.

According to some embodiments of the present disclosure, the display apparatus, which may prevent defects due to static electricity from occurring, and the multi-screen display apparatus including the same may be provided.

According to some embodiments of the present disclosure, the display apparatus having no bezel and the multi-screen display apparatus including the same may be provided.

According to some embodiments of the present disclosure, the multi-screen display apparatus, which may display an image without a sense of disconnection, may be provided.

It will be apparent to those skilled in the art that the present disclosure described above is not limited by the above-described embodiments and the accompanying drawings and that various substitutions, modifications and variations may be formed in the present disclosure without departing from the spirit or scope of the disclosures. Consequently, the scope of the present disclosure is intended to cover all variations or modifications derived from the meaning, scope and equivalent concept of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a substrate having a display portion;
a plurality of pixels disposed in the display portion;
pad portions spaced apart from the plurality of pixels and disposed at an edge portion of one side of the substrate;
a dummy portion adjacent to the display portion and disposed between the pad portion and the plurality of pixels;
a pad connection line crossing the dummy portion and electrically connected to each of the pad portions; and
a connection portion electrically connecting the dummy portion with the pad connection line.

2. The display apparatus of claim 1, further comprising a cross area where the dummy portion and the pad connection line cross each other,
wherein the connection portion electrically connects the dummy portion with the pad connection line at the cross area.

3. The display apparatus of claim 1, further comprising:
a first middle insulating layer disposed between the connection portion and the pad connection line; and
a second middle insulating layer disposed between the dummy portion and the connection portion,
wherein the first middle insulating layer includes a first contact hole for electrically connecting the connection portion with the pad connection line,
wherein the second middle insulating layer includes a second contact hole for electrically connecting the dummy portion with the connection portion, and
wherein the first contact hole overlaps the second contact hole in the cross area.

4. The display apparatus of claim 3, wherein the connection portion is electrically connected to the pad connection line through the first contact hole, and
wherein the dummy portion is electrically connected to the connection portion through the second contact hole.

5. The display apparatus of claim 3, wherein the first middle insulating layer includes a buffer layer disposed on the pad connection line and an interlayer insulating layer disposed on the buffer layer,
wherein the second middle insulating layer includes a passivation layer disposed on the interlayer insulating layer,
wherein the first contact hole includes a first via hole passing through the buffer layer disposed on the pad connection line and a second via hole passing through the interlayer insulating layer disposed on the first via hole,
wherein the second contact hole includes a third via hole passing through the passivation layer disposed on the second via hole,
wherein the connection portion is electrically connected to the pad connection line through the first via hole and the second via hole, and
wherein the dummy portion is electrically connected to the connection portion through the third via hole.

6. The display apparatus of claim 1, further comprising:
a dam disposed at an edge portion of the substrate to surround the display portion; and
a light emitting element layer including an organic light emitting layer disposed on the display portion and the dam and a common electrode disposed on the organic light emitting layer,
wherein each of the organic light emitting layer and the common electrode is disconnected by the dummy portion.

7. The display apparatus of claim 6, wherein the dummy portion includes a first dummy line disposed between the pad portion and the dam and a second dummy line disposed between the first dummy line and the dam,
wherein the pad portion includes a first pad member and a second pad member, which are disposed to be spaced apart from each other at the edge portion of the substrate,
wherein the pad connection line includes a first pad connection line electrically connected to the first pad member and a second pad connection line electrically connected to the second pad member,
wherein the first dummy line includes a first dummy electrode electrically connected to the first pad connection line while crossing the first pad connection line, and
wherein the second dummy line includes a second dummy electrode electrically connected to the second pad connection line while crossing the second pad connection line.

8. The display apparatus of claim 7, further comprising:
a buffer layer disposed on the pad connection line;
an interlayer insulating layer disposed on the buffer layer; and
a passivation layer disposed between the interlayer insulating layer and the first dummy electrode,
wherein a width of the first dummy electrode is wider than that of the passivation layer.

9. The display apparatus of claim 7, further comprising an undercut portion disposed between the first dummy line and the second dummy line,
wherein the undercut portion is disposed along the first dummy line or the second dummy line.

10. The display apparatus of claim 7, wherein the dummy portion includes a third dummy line disposed between the dam and the display portion,
wherein the pad portion further includes a third pad member spaced apart from the second pad member at the edge portion of the substrate,
wherein the pad connection line further includes a third pad connection line electrically connected to the third pad member,
wherein the third dummy line includes a third dummy electrode electrically connected to the third pad connection line while crossing the third pad connection line, and
wherein a width of the third dummy electrode is the same as or wider than that of the first dummy electrode.

11. The display apparatus of claim 1, further comprising:
a cross area where the dummy portion and the pad connection line cross each other; and
a non-cross area adjacent to the cross area, in which the dummy portion and the pad connection line do not cross each other,
wherein the pad connection line includes a protruded line protruded toward the non-cross area, and
wherein the connection portion electrically connects the dummy portion with the protruded line on the protruded line.

12. The display apparatus of claim 11, further comprising:
a first middle insulating layer disposed between the connection portion and the protruded line; and
a second middle insulating layer disposed between the dummy portion and the connection portion,
wherein the first middle insulating layer includes a first contact hole for electrically connecting the connection portion with the protruded line,
wherein the second middle insulating layer includes a second contact hole for electrically connecting the dummy portion with the connection portion, and
wherein the first contact hole is disposed to be spaced apart from the second contact hole on the protruded line.

13. The display apparatus of claim 12, wherein the connection portion includes:
a first connection line that is in contact with the protruded line and extended from the first contact hole to a space between the first contact hole and the second contact hole; and
a second connection line electrically connected to the first connection line and extended to the second contact hole to be in contact with the dummy portion, and
wherein the first connection line is in contact with the second connection line between the first contact hole and the second contact hole.

14. The display apparatus of claim 12, wherein the first middle insulating layer includes a buffer layer disposed on the protruded line and an interlayer insulating layer disposed on the buffer layer,
wherein the second middle insulating layer includes a passivation layer disposed on the interlayer insulating layer,
wherein the first contact hole includes a first via hole passing through the buffer layer and a second via hole passing through the interlayer insulating layer disposed on the first via hole,
wherein the second contact hole includes a third via hole passing through the passivation layer disposed on the second via hole,
wherein the first via hole overlaps the second via hole, and
wherein the third via hole does not overlap the second via hole.

15. The display apparatus of claim 11, further comprising a dam disposed at the edge portion of the substrate to surround the display portion,
wherein the dummy portion includes a first dummy line disposed between the pad portion and the dam and a second dummy line disposed between the first dummy line and the dam,
wherein the pad portion includes a first pad member and a second pad member, which are disposed to be spaced apart from each other at an edge portion of the substrate,
wherein the pad connection line includes a first pad connection line electrically connected to the first pad member and a second pad connection line electrically connected to the second pad member,
wherein the first pad connection line includes a first protruded line protruded toward the non-cross area,
wherein the second pad connection line includes a second protruded line protruded toward the non-cross area,
wherein the first dummy line includes a first dummy electrode electrically connected to the first protruded line on the first protruded line, and
wherein the second dummy line includes a second dummy electrode electrically connected to the second protruded line on the second protruded line.

16. The display apparatus of claim 15, wherein the pad portion further includes a third pad member spaced apart from the second pad member at the edge portion of the substrate,
wherein the pad connection line further includes a third pad connection line electrically connected to the third pad member,
wherein the first protruded line is disposed between the first pad connection line and the second pad connection line, and
wherein the second protruded line is disposed between the second pad connection line and the third pad connection line.

17. The display apparatus of claim 15, wherein a width of the first dummy electrode overlapped with the first protruded line is wider than that of the first dummy electrode overlapped with the cross area.

18. The display apparatus of claim 17, wherein the second dummy electrode includes a first sub-dummy electrode disposed to face the first protruded line and a second sub-dummy electrode electrically connected to the first sub-dummy electrode, and
wherein a width of the first sub-dummy electrode is narrower than that of the second sub-dummy electrode.

19. The display apparatus of claim 1, wherein sides of the display portion are aligned on an outer side of the substrate or a size of the display portion is the same as that of the substrate.

20. The display apparatus of claim 19, wherein an outermost pixel of the plurality of pixels includes at least one dummy portion, the pad portion and the connection portion, or
the plurality of pixels are disposed on the substrate to have a pixel pitch along a first direction and a second direction crossing the first direction, and an interval between a central portion of the outermost pixel and the outer side of the substrate is a half or less of the pixel pitch.

21. A multi-screen display apparatus comprising:
a plurality of display modules disposed along at least one of a first direction and a second direction crossing the first direction,
wherein each of the plurality of display modules includes a display apparatus including comprising:
a substrate having a display portion;
a plurality of pixels displayed in the display portion;
a pad portion spaced apart from the plurality of pixels and disposed at an edge portion of one side of the substrate;
a dummy portion adjacent to the display portion and disposed between the pad portion and the plurality of pixels;
a pad connection line crossing the dummy portion and electrically connected to each of the pad portions; and
a connection portion electrically connecting the dummy portion with the pad connection line.

22. The multi-screen display apparatus of claim 21, wherein sides of the display portion are aligned on outer side of the substrate or a size of the display portion is the same as that of the substrate.

23. The multi-screen display apparatus of claim 22, wherein an outermost pixel of the plurality of pixels includes at least one dummy portion, the pad portion and the connection portion, or
the plurality of pixels are disposed on the substrate to have a pixel pitch along the first direction and the second direction crossing the first direction, and an interval between a central portion of the outermost pixel and the outer side of the substrate is a half or less of the pixel pitch.
